(19) United States
(12) Patent Application Publication
(10) Pub. No.: US 2023/0031457 A1
(43) Pub. Date: Feb. 2, 2023

(54) METHODS, SYSTEMS, APPARATUS, AND ARTICLES OF MANUFACTURE TO CRIMP A TUBE

(71) Applicant: Intel Corporation, Santa Clara, CA (US)

(72) Inventors: Phil Geng, Washougal, WA (US); Ralph Miele, Hillsboro, OR (US); Christopher Gonzalez, Hillsboro, OR (US); Timothy Gates, Hillsboro, OR (US); Sanjoy Saha, Portland, OR (US); Ashish Gupta, Portland, OR (US); Sandeep Ahuja, Portland, OR (US)

(21) Appl. No.: 17/957,436

(22) Filed: Sep. 30, 2022

(51) Int. Cl. B21C 37/16

(52) U.S. Cl. CPC B21C 37/16

(57) ABSTRACT

Methods, systems, apparatus, and articles of manufacture to crimp a tube are disclosed. An example crimp disclosed herein includes a first crimp section extending between a first end of the crimp and a point along the crimp between the first end and a second end, a first inner diameter of the first crimp section constant between the first end and the point, and a second crimp section adjacent the first crimp section, the second crimp section extending between the point and the second end, a second inner diameter of the second crimp section to increase from the point to the second end.

### FIELD OF THE DISCLOSURE

This disclosure relates generally to fluid systems and, more particularly, to methods, systems, apparatus, and articles of manufacture to crimp a tube.

### BACKGROUND

During operation of an electronic device, one or more electronic components (e.g., hardware components) of the electronic device may generate heat. As such, many electronic devices include a cooling system to cool the electronic components. The cooling system commonly passes fluid (e.g., liquid and/or air) across and/or near a surface of the electronic components to draw heat therefrom. In some cases, the fluid flows through conduit (e.g., tubes) of the cooling system to reach the electronic components.

### BRIEF DESCRIPTION OF THE DRAWINGS

FIG. 1 illustrates one or more example environments in which teachings of this disclosure may be implemented.

FIG. 2 illustrates at least one example of a data center for executing workloads with disaggregated resources.

FIG. 3 illustrates at least one example of a pod that may be included in the data center of FIG. 2.

FIG. 4 is a perspective view of at least one example of a rack that may be included in the pod of FIG. 3.

FIG. 5 is a side elevation view of the rack of FIG. 4.

FIG. 6 is a perspective view of the rack of FIG. 4 having a sled mounted therein.

FIG. 7 is a is a block diagram of at least one example of a top side of the sled of FIG. 6.

FIG. 8 is a block diagram of at least one example of a bottom side of the sled of FIG. 7.

FIG. 9 is a block diagram of at least one example of a compute sled usable in the data center of FIG. 2.

FIG. 10 is a top perspective view of at least one example of the compute sled of FIG. 9.

FIG. 11 is a block diagram of at least one example of an accelerator sled usable in the data center of FIG. 2.

FIG. 12 is a top perspective view of at least one example of the accelerator sled of FIG. 10.

FIG. 13 is a block diagram of at least one example of a storage sled usable in the data center of FIG. 2.

FIG. 14 is a top perspective view of at least one example of the storage sled of FIG. 13.

FIG. 15 is a block diagram of at least one example of a memory sled usable in the data center of FIG. 2.

FIG. 16 is a block diagram of a system that may be established within the data center of FIG. 2 to execute workloads with managed nodes of disaggregated resources.

FIG. 17 illustrates a cooling system in which examples disclosed herein may be implemented.

FIG. 18 illustrates a cross-sectional view of one of the tubes of FIG. 17 coupled to a respective one of the connectors of FIG. 17.

FIG. 19 illustrates a cross-sectional view of an example tapered crimp constructed in accordance with teachings of this disclosure.

FIG. 20A illustrates a cross-sectional view of an alternative implementation of the example tapered crimp of FIG. 19.

FIG. 20B illustrates a cross-sectional view of the example tapered crimp of FIG. 20A having a different shape of the outer surface.

FIG. 21A illustrates a cross-sectional view of an example stepped crimp constructed in accordance with teachings of this disclosure.

FIG. 21B illustrates a cross-sectional view of a second example stepped crimp.

FIG. 22A illustrates an example piecewise crimp constructed in accordance with teachings of this disclosure.

FIG. 22B illustrates the example piecewise crimp of FIG. 22A crimped on the example tube.

FIG. 22C illustrates a second example piecewise crimp crimped on the example tube.

FIG. 22D illustrates the example piecewise crimp of FIG. 22B including example indentations generated as a result of crimping on the example tube.

FIG. 23A illustrates the example tapered crimp of FIGS. 19 and/or 20A crimping the example tube onto an example connector 2300.

FIG. 23B illustrates the example piecewise crimp of FIGS. 22A and/or 22B crimping the example tube onto the example connector of FIG. 23A.

FIG. 24 is a flowchart representative of an example method of installing the example piecewise crimp of FIGS. 22A and/or 22B onto the example tube of FIG. 22A.

FIG. 25 is a flowchart representative of an example method of manufacturing the example tapered crimp of FIG. 19 and/or the example stepped crimp of FIG. 21A.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

### DETAILED DESCRIPTION

During operation of an electronic device, one or more electronic components (e.g., a processor chip, a memory chip, etc.) of the electronic device may generate heat. In some cases, excessive heat may cause overheating and, thus, degradation in performance of the electronic components. To prevent overheating, some electronic devices include a cooling system operatively coupled to one or more of the electronic components to facilitate heat transfer therefrom. Some cooling systems utilize liquids and/or gases (e.g., air) to cool the electronic components.

In some electronic devices, the use of liquids to cool electronic components is being explored for its benefits over more traditional air cooling systems, as there are increasing needs to address thermal management risks resulting from increased thermal design power in high performance systems (e.g., CPU and/or GPU servers in data centers, cloud computing, edge computing, and the like). More particularly, relative to air, liquid has inherent advantages of higher specific heat (when no boiling is involved) and higher latent heat of vaporization (when boiling is involved). In some instances, liquid can be used to indirectly cool electronic components by cooling a cold plate that is thermally coupled to the electronic components. An alternative approach is to directly immerse electronic components in the cooling liquid. In direct immersion cooling, the liquid can be in direct contact with the electronic components to directly draw away heat from the electronic components. To enable the cooling liquid to be in direct contact with electronic components, the cooling liquid is electrically insulative (e.g., a dielectric liquid).

In some cooling systems, the cooling liquid passes through a series of conduits (e.g., tubes, pipes, hoses) to reach the electronic components to be cooled. In some instances, the conduits are mechanically and/or fluidly coupled to connectors (e.g., fittings, barb fittings, etc.), where the connectors are used to couple the conduits to one another and/or to the electronic components (and/or cold plates or other cooling devices adjacent to and/or thermally coupled to the electronic components). In some such instances, a crimp (e.g., a crimp sleeve) can be placed and/or fitted around the conduit and the corresponding connector, and the crimp can be tightened (e.g. a cross-sectional area of the crimp can be reduced) to clamp the conduit onto the connector. As a result, the crimp can prevent and/or reduce decoupling of the conduit onto the connector. Furthermore, the crimp can sealably couple the conduit to the connector to prevent and/or reduce leakage of fluid through the conduit and/or the connector. However, some crimps generate stress on a location of the conduit proximate an edge of the crimp, where such stress may lead to rupture of the conduit and, thus, leakage of the fluid therefrom. In such cases, the conduit typically requires repair or replacement, thus increasing parts and/or manufacturing costs associated with the cooling system and/or the electronic device.

Examples disclosed herein reduce stress concentration on the conduit by using a crimp sleeve (e.g., a tapered crimp, a stepped crimp, a piecewise crimp) to distribute the stress across a surface of the conduit. Crimp sleeves are also referred to herein as simply crimps for short. In examples disclosed herein, an example crimp sleeve includes a first crimp section (e.g., a first crimp segment) to have a first inner diameter at a first end of the crimp sleeve, and a second crimp section to have a second inner diameter at a second end of the crimp sleeve, where the second inner diameter is greater than the first inner diameter. In some examples, the first inner diameter is constant (e.g., not changing, not increasing nor decreasing) along a first length of the first crimp section. As used herein, the term “constant” as applied to a diameter or other dimension does not require the diameter or dimension to be exactly constant but includes variation in the diameter or dimension that can arise due to real-world imperfections but that remain within manufacturing tolerances. Thus, the terms “constant” and “substantially constant” can be used interchangeably. As used herein, the term “crimp” can be a noun referring to a crimp sleeve, and/or can be used as a verb meaning to tighten, to reduce a cross-sectional area of, etc.

In some examples, the second inner diameter gradually increases along a second length of the second crimp section from a point proximate the first crimp section to the second end of the crimp sleeve. In some examples, the second inner diameter is substantially constant along the second length of the second crimp section. In some examples, the first crimp section is crimped onto an end portion of a tube to sealably couple the end portion to a barbed portion of a connector, and the second crimp section is crimped onto the tube proximate an end of the first crimp section (e.g., away from the connector). In some examples, the second crimp section is positioned at or near a location of the tube at which stress is generated due to crimping of the end portion of the tube. In some examples, the second crimp section distributes the stress across a surface of the tube, thus preventing and/or reducing likelihood of rupture of the tube resulting from a stress concentration on the tube.

Advantageously, examples disclosed herein reduce parts cost and/or repair costs associated with repair and/or replacement of tubes in a liquid cooling system. Furthermore, by improving reliability of the tubes in the liquid cooling system, examples disclosed herein maintain efficiency of cooling of an electronic device by the liquid cooling system, thus preventing and/or reducing likelihood of overheating of the electronic device and/or reducing the likelihood of short circuits arising from leakage of cooling fluid onto electronic components of the device.

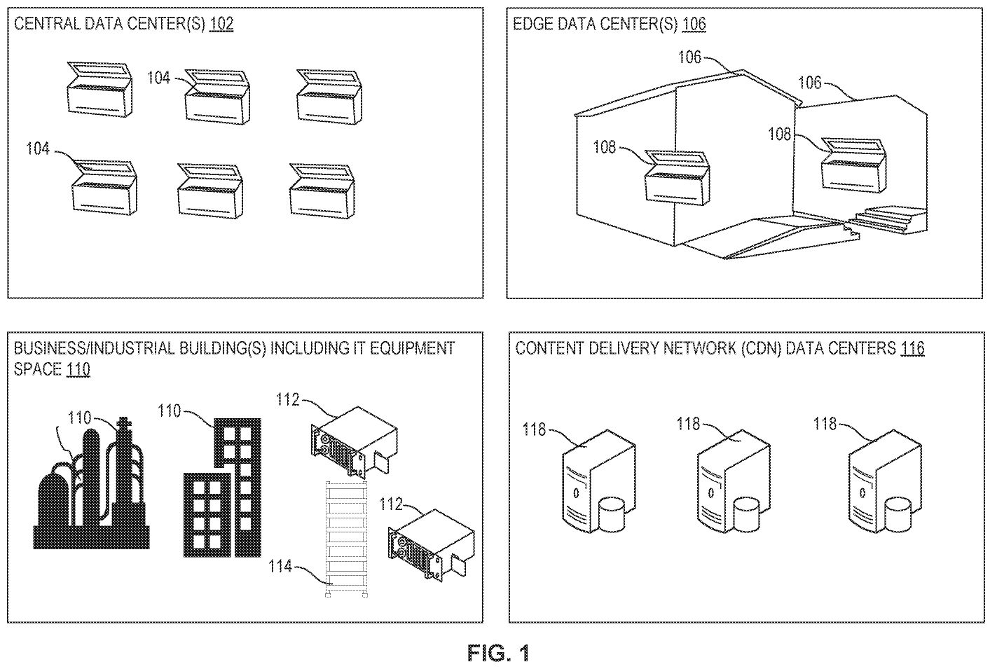

FIG. 1 illustrates one or more example environments in which teachings of this disclosure may be implemented. The example environment(s) of FIG. 1 can include one or more central data centers 102. The central data center(s) 102 can store a large number of servers used by, for instance, one or more organizations for data processing, storage, etc. As illustrated in FIG. 1, the central data center(s) 102 include a plurality of immersion tank(s) 104 to facilitate cooling of the servers and/or other electronic components stored at the central data center(s) 102. The immersion tank(s) 104 can provide for single-phase immersion cooling or two-phase immersion cooling.

The example environments of FIG. 1 can be part of an edge computing system. For instance, the example environments of FIG. 1 can include edge data centers or micro-data centers 106. The edge data center(s) 106 can include, for example, data centers located at a base of a cell tower. In some examples, the edge data center(s) 106 are located at or near a top of a cell tower and/or other utility pole. The edge data center(s) 106 include respective housings that store server(s), where the server(s) can be in communication with, for instance, the server(s) stored at the central data center(s) 102, client devices, and/or other computing devices in the edge network. Example housings of the edge data center(s) 106 may include materials that form one or more exterior surfaces that partially or fully protect contents therein, in which protection may include weather protection, hazardous environment protection (e.g., EMI, vibration, extreme temperatures), and/or enable submergibility. Example housings may include power circuitry to provide power for stationary and/or portable implementations, such as AC power inputs, DC power inputs, AC/DC or DC/AC converter(s), power regulators, transformers, charging circuitry, batteries, wired inputs and/or wireless power inputs. As illustrated in FIG. 1, the edge data center(s) 106 can include immersion tank(s) 108 to store server(s) and/or other electronic component(s) located at the edge data center(s) 106.

The example environment(s) of FIG. 1 can include buildings 110 for purposes of business and/or industry that store information technology (IT) equipment in, for example, one or more rooms of the building(s) 110. For example, as represented in FIG. 1, server(s) 112 can be stored with server rack(s) 114 that support the server(s) 112 (e.g., in an opening of slot of the rack 114). In some examples, the server(s) 112 located at the buildings 110 include on-premise server(s) of an edge computing network, where the on-premise server(s) are in communication with remote server(s) (e.g., the server(s) at the edge data center(s) 106) and/or other computing device(s) within an edge network.

The example environment(s) of FIG. 1 include content delivery network (CDN) data center(s) 116. The CDN data center(s) 116 of this example include server(s) 118 that cache content such as images, webpages, videos, etc. accessed via user devices. The server(s) 118 of the CDN data centers 116 can be disposed in immersion cooling tank(s) such as the immersion tanks 104, 108 shown in connection with the data centers 102, 106.

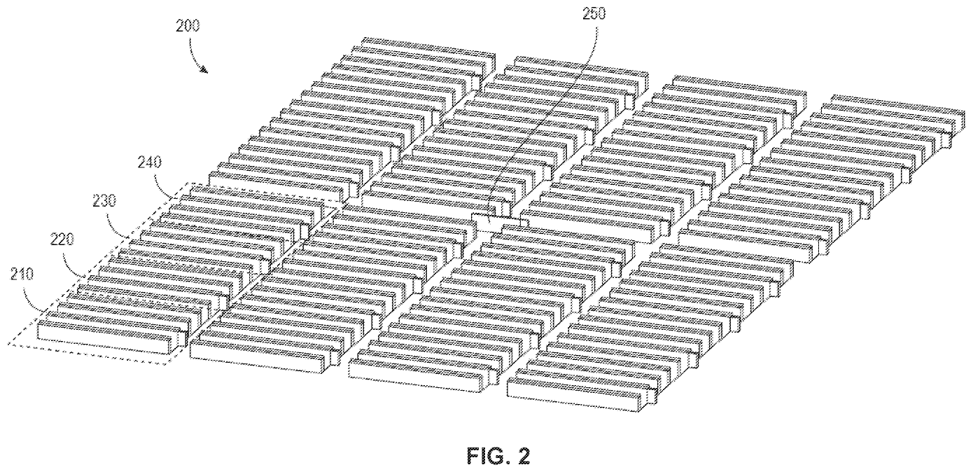

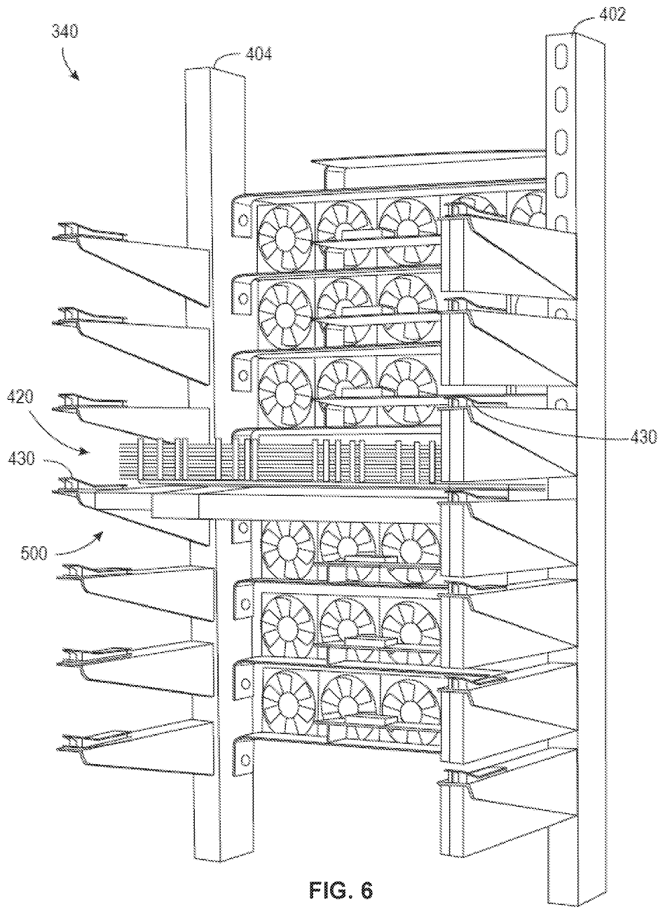

In some instances, the example data centers 102, 106, 116 and/or building(s) 110 of FIG. 1 include servers and/or other electronic components that are cooled independent of immersion tanks (e.g., the immersion tanks 104, 108) and/or an associated immersion cooling system. That is, in some examples, some or all of the servers and/or other electronic components in the data centers 102, 106, 116 and/or building(s) 110 can be cooled by air and/or liquid coolants without immersing the servers and/or other electronic components therein. Thus, in some examples, the immersion tanks 104, 108 of FIG. 1 may be omitted. Further, the example data centers 102, 106, 116 and/or building(s) 110 of FIG. 1 can correspond to, be implemented by, and/or be adaptations of the example data center 200 described in further detail below in connection with FIGS. 2-16.

Although a certain number of cooling tank(s) and other component(s) are shown in the figures, any number of such components may be present. Also, the example cooling data centers and/or other structures or environments disclosed herein are not limited to arrangements of the size that are depicted in FIG. 1. For instance, the structures containing example cooling systems and/or components thereof disclosed herein can be of a size that includes an opening to accommodate service personnel, such as the example data center(s) 106 of FIG. 1, but can also be smaller (e.g., a “doghouse” enclosure). For instance, the structures containing example cooling systems and/or components thereof disclosed herein can be sized such that access (e.g., the only access) to an interior of the structure is a port for service personnel to reach into the structure. In some examples, the structures containing example cooling systems and/or components thereof disclosed herein are be sized such that only a tool can reach into the enclosure because the structure may be supported by, for a utility pole or radio tower, or a larger structure.

FIG. 2 illustrates an example data center 200 in which disaggregated resources may cooperatively execute one or more workloads (e.g., applications on behalf of customers). The illustrated data center 200 includes multiple platforms 210, 220, 230, 240 (referred to herein as pods), each of which includes one or more rows of racks. Although the data center 200 is shown with multiple pods, in some examples, the data center 200 may be implemented as a single pod. As described in more detail herein, a rack may house multiple sleds. A sled may be primarily equipped with a particular type of resource (e.g., memory devices, data storage devices, accelerator devices, general purpose processors), i.e., resources that can be logically coupled to form a composed node. Some such nodes may act as, for example, a server. In the illustrative example, the sleds in the pods 210, 220, 230, 240 are connected to multiple pod switches (e.g., switches that route data communications to and from sleds within the pod). The pod switches, in turn, connect with spine switches 250 that switch communications among pods (e.g., the pods 210, 220, 230, 240) in the data center 200. In some examples, the sleds may be connected with a fabric using Intel Omni-Path™ technology. In other examples, the sleds may be connected with other fabrics, such as InfiniBand or Ethernet. As described in more detail herein, resources within the sleds in the data center 200 may be allocated to a group (referred to herein as a “managed node”) containing resources from one or more sleds to be collectively utilized in the execution of a workload. The workload can execute as if the resources belonging to the managed node were located on the same sled. The resources in a managed node may belong to sleds belonging to different racks, and even to different pods 210, 220, 230, 240. As such, some resources of a single sled may be allocated to one managed node while other resources of the same sled are allocated to a different managed node (e.g., first processor circuitry assigned to one managed node and second processor circuitry of the same sled assigned to a different managed node).

A data center including disaggregated resources, such as the data center 200, can be used in a wide variety of contexts, such as enterprise, government, cloud service provider, and communications service provider (e.g., Telco's), as well in a wide variety of sizes, from cloud service provider mega-data centers that consume over 200,000 sq. ft. to single- or multi-rack installations for use in base stations.

In some examples, the disaggregation of resources is accomplished by using individual sleds that include predominantly a single type of resource (e.g., compute sleds including primarily compute resources, memory sleds including primarily memory resources). The disaggregation of resources in this manner, and the selective allocation and deallocation of the disaggregated resources to form a managed node assigned to execute a workload, improves the operation and resource usage of the data center 200 relative to typical data centers. Such typical data centers include hyperconverged servers containing compute, memory, storage and perhaps additional resources in a single chassis. For example, because a given sled will contain mostly resources of a same particular type, resources of that type can be upgraded independently of other resources. Additionally, because different resource types (processors, storage, accelerators, etc.) typically have different refresh rates, greater resource utilization and reduced total cost of ownership may be achieved. For example, a data center operator can upgrade the processor circuitry throughout a facility by only swapping out the compute sleds. In such a case, accelerator and storage resources may not be contemporaneously upgraded and, rather, may be allowed to continue operating until those resources are scheduled for their own refresh. Resource utilization may also increase. For example, if managed nodes are composed based on requirements of the workloads that will be running on them, resources within a node are more likely to be fully utilized. Such utilization may allow for more managed nodes to run in a data center with a given set of resources, or for a data center expected to run a given set of workloads, to be built using fewer resources.

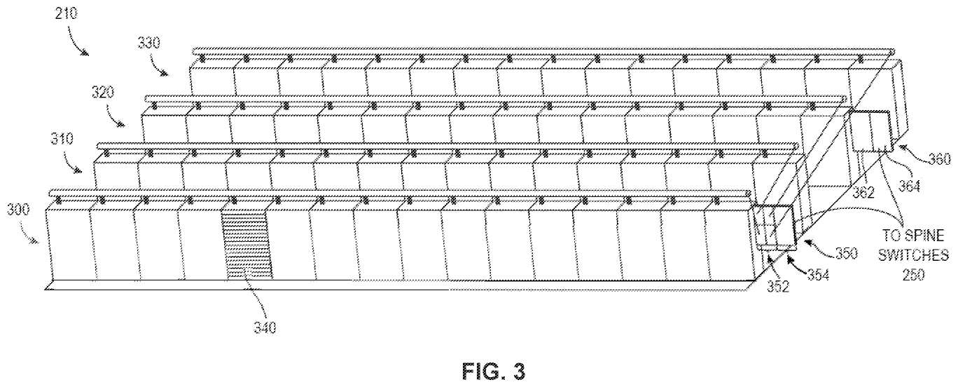

Referring now to FIG. 3, the pod 210, in the illustrative example, includes a set of rows 300, 310, 320, 330 of racks 340. Individual ones of the racks 340 may house multiple sleds (e.g., sixteen sleds) and provide power and data connections to the housed sleds, as described in more detail herein. In the illustrative example, the racks are connected to multiple pod switches 350, 360. The pod switch 350 includes a set of ports 352 to which the sleds of the racks of the pod 210 are connected and another set of ports 354 that connect the pod 210 to the spine switches 250 to provide connectivity to other pods in the data center 200. Similarly, the pod switch 360 includes a set of ports 362 to which the sleds of the racks of the pod 210 are connected and a set of ports 364 that connect the pod 210 to the spine switches 250. As such, the use of the pair of switches 350, 360 provides an amount of redundancy to the pod 210. For example, if either of the switches 350, 360 fails, the sleds in the pod 210 may still maintain data communication with the remainder of the data center 200 (e.g., sleds of other pods) through the other switch 350, 360. Furthermore, in the illustrative example, the switches 250, 350, 360 may be implemented as dual-mode optical switches, capable of routing both Ethernet protocol communications carrying Internet Protocol (IP) packets and communications according to a second, high-performance link-layer protocol (e.g., PCI Express) via optical signaling media of an optical fabric.

It should be appreciated that any one of the other pods 220, 230, 240 (as well as any additional pods of the data center 200) may be similarly structured as, and have components similar to, the pod 210 shown in and disclosed in regard to FIG. 3 (e.g., a given pod may have rows of racks housing multiple sleds as described above). Additionally, while two pod switches 350, 360 are shown, it should be understood that in other examples, a different number of pod switches may be present, providing even more failover capacity. In other examples, pods may be arranged differently than the rows-of-racks configuration shown in FIGS. 2 and 3. For example, a pod may include multiple sets of racks arranged radially, i.e., the racks are equidistant from a center switch.

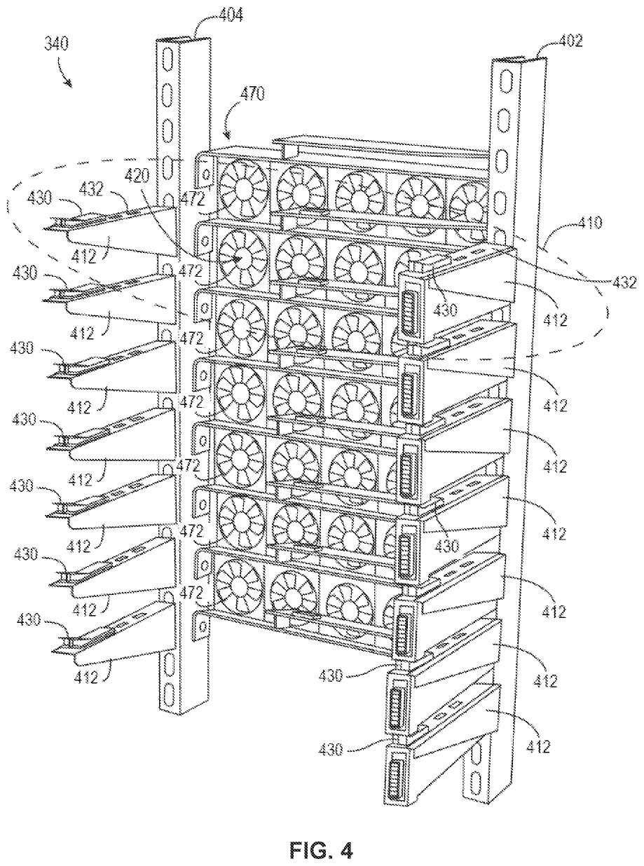

FIGS. 4-6 illustrate an example rack 340 of the data center 200. As shown in the illustrated example, the rack 340 includes two elongated support posts 402, 404, which are arranged vertically. For example, the elongated support posts 402, 404 may extend upwardly from a floor of the data center 200 when deployed. The rack 340 also includes one or more horizontal pairs 410 of elongated support arms 412 (identified in FIG. 4 via a dashed ellipse) configured to support a sled of the data center 200 as discussed below. One elongated support arm 412 of the pair of elongated support arms 412 extends outwardly from the elongated support post 402 and the other elongated support arm 412 extends outwardly from the elongated support post 404.

In the illustrative examples, at least some of the sleds of the data center 200 are chassis-less sleds. That is, such sleds have a chassis-less circuit board substrate on which physical resources (e.g., processors, memory, accelerators, storage, etc.) are mounted as discussed in more detail below. As such, the rack 340 is configured to receive the chassis-less sleds. For example, a given pair 410 of the elongated support arms 412 defines a sled slot 420 of the rack 340, which is configured to receive a corresponding chassis-less sled. To do so, the elongated support arms 412 include corresponding circuit board guides 430 configured to receive the chassis-less circuit board substrate of the sled. The circuit board guides 430 are secured to, or otherwise mounted to, a top side 432 of the corresponding elongated support arms 412. For example, in the illustrative example, the circuit board guides 430 are mounted at a distal end of the corresponding elongated support arm 412 relative to the corresponding elongated support post 402, 404. For clarity of FIGS. 4-6, not every circuit board guide 430 may be referenced in each figure. In some examples, at least some of the sleds include a chassis and the racks 340 are suitably adapted to receive the chassis.

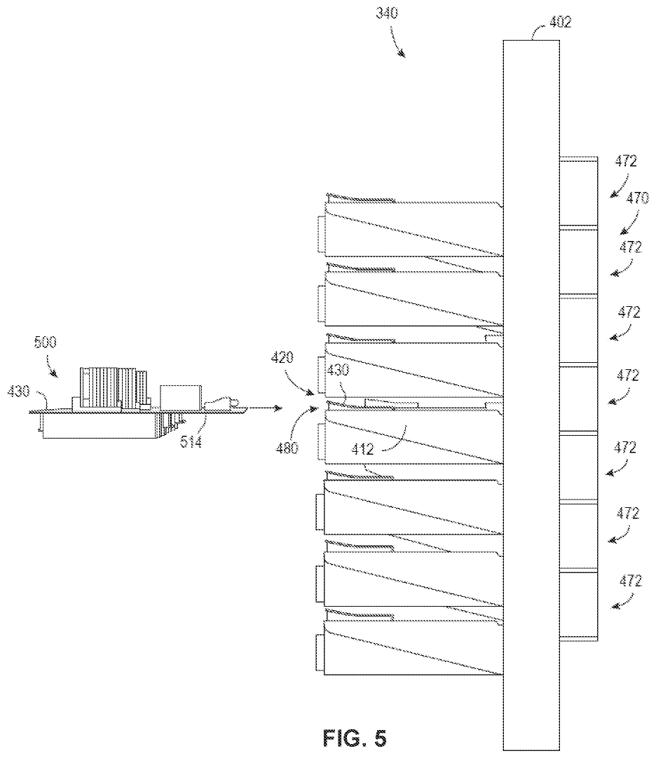

The circuit board guides 430 include an inner wall that defines a circuit board slot 480 configured to receive the chassis-less circuit board substrate of a sled 500 when the sled 500 is received in the corresponding sled slot 420 of the rack 340. To do so, as shown in FIG. 5, a user (or robot) aligns the chassis-less circuit board substrate of an illustrative chassis-less sled 500 to a sled slot 420. The user, or robot, may then slide the chassis-less circuit board substrate forward into the sled slot 420 such that each side edge 514 of the chassis-less circuit board substrate is received in a corresponding circuit board slot 480 of the circuit board guides 430 of the pair 410 of elongated support arms 412 that define the corresponding sled slot 420 as shown in FIG. 5. By having robotically accessible and robotically manipulable sleds including disaggregated resources, the different types of resource can be upgraded independently of one other and at their own optimized refresh rate. Furthermore, the sleds are configured to blindly mate with power and data communication cables in the rack 340, enhancing their ability to be quickly removed, upgraded, reinstalled, and/or replaced. As such, in some examples, the data center 200 may operate (e.g., execute workloads, undergo maintenance and/or upgrades, etc.) without human involvement on the data center floor. In other examples, a human may facilitate one or more maintenance or upgrade operations in the data center 200.

It should be appreciated that the circuit board guides 430 are dual sided. That is, a circuit board guide 430 includes an inner wall that defines a circuit board slot 480 on each side of the circuit board guide 430. In this way, the circuit board guide 430 can support a chassis-less circuit board substrate on either side. As such, a single additional elongated support post may be added to the rack 340 to turn the rack 340 into a two-rack solution that can hold twice as many sled slots 420 as shown in FIG. 4. The illustrative rack 340 includes seven pairs 410 of elongated support arms 412 that define seven corresponding sled slots 420. The sled slots 420 are configured to receive and support a corresponding sled 500 as discussed above. In other examples, the rack 340 may include additional or fewer pairs 410 of elongated support arms 412 (i.e., additional or fewer sled slots 420). It should be appreciated that because the sled 500 is chassis-less, the sled 500 may have an overall height that is different than typical servers. As such, in some examples, the height of a given sled slot 420 may be shorter than the height of a typical server (e.g., shorter than a single rank unit, referred to as “1U”). That is, the vertical distance between pairs 410 of elongated support arms 412 may be less than a standard rack unit “1U.” Additionally, due to the relative decrease in height of the sled slots 420, the overall height of the rack 340 in some examples may be shorter than the height of traditional rack enclosures. For example, in some examples, the elongated support posts 402, 404 may have a length of six feet or less. Again, in other examples, the rack 340 may have different dimensions. For example, in some examples, the vertical distance between pairs 410 of elongated support arms 412 may be greater than a standard rack unit “1U”. In such examples, the increased vertical distance between the sleds allows for larger heatsinks to be attached to the physical resources and for larger fans to be used (e.g., in the fan array 470 described below) for cooling the sleds, which in turn can allow the physical resources to operate at increased power levels. Further, it should be appreciated that the rack 340 does not include any walls, enclosures, or the like. Rather, the rack 340 is an enclosure-less rack that is opened to the local environment. In some cases, an end plate may be attached to one of the elongated support posts 402, 404 in those situations in which the rack 340 forms an end-of-row rack in the data center 200.

In some examples, various interconnects may be routed upwardly or downwardly through the elongated support posts 402, 404. To facilitate such routing, the elongated support posts 402, 404 include an inner wall that defines an inner chamber in which interconnects may be located. The interconnects routed through the elongated support posts 402, 404 may be implemented as any type of interconnects including, but not limited to, data or communication interconnects to provide communication connections to the sled slots 420, power interconnects to provide power to the sled slots 420, and/or other types of interconnects.

The rack 340, in the illustrative example, includes a support platform on which a corresponding optical data connector (not shown) is mounted. Such optical data connectors are associated with corresponding sled slots 420 and are configured to mate with optical data connectors of corresponding sleds 500 when the sleds 500 are received in the corresponding sled slots 420. In some examples, optical connections between components (e.g., sleds, racks, and switches) in the data center 200 are made with a blind mate optical connection. For example, a door on a given cable may prevent dust from contaminating the fiber inside the cable. In the process of connecting to a blind mate optical connector mechanism, the door is pushed open when the end of the cable approaches or enters the connector mechanism. Subsequently, the optical fiber inside the cable may enter a gel within the connector mechanism and the optical fiber of one cable comes into contact with the optical fiber of another cable within the gel inside the connector mechanism.

The illustrative rack 340 also includes a fan array 470 coupled to the cross-support arms of the rack 340. The fan array 470 includes one or more rows of cooling fans 472, which are aligned in a horizontal line between the elongated support posts 402, 404. In the illustrative example, the fan array 470 includes a row of cooling fans 472 for the different sled slots 420 of the rack 340. As discussed above, the sleds 500 do not include any on-board cooling system in the illustrative example and, as such, the fan array 470 provides cooling for such sleds 500 received in the rack 340. In other examples, some or all of the sleds 500 can include on-board cooling systems. Further, in some examples, the sleds 500 and/or the racks 340 may include and/or incorporate a liquid and/or immersion cooling system to facilitate cooling of electronic component(s) on the sleds 500. The rack 340, in the illustrative example, also includes different power supplies associated with different ones of the sled slots 420. A given power supply is secured to one of the elongated support arms 412 of the pair 410 of elongated support arms 412 that define the corresponding sled slot 420. For example, the rack 340 may include a power supply coupled or secured to individual ones of the elongated support arms 412 extending from the elongated support post 402. A given power supply includes a power connector configured to mate with a power connector of a sled 500 when the sled 500 is received in the corresponding sled slot 420. In the illustrative example, the sled 500 does not include any on-board power supply and, as such, the power supplies provided in the rack 340 supply power to corresponding sleds 500 when mounted to the rack 340. A given power supply is configured to satisfy the power requirements for its associated sled, which can differ from sled to sled. Additionally, the power supplies provided in the rack 340 can operate independent of each other. That is, within a single rack, a first power supply providing power to a compute sled can provide power levels that are different than power levels supplied by a second power supply providing power to an accelerator sled. The power supplies may be controllable at the sled level or rack level, and may be controlled locally by components on the associated sled or remotely, such as by another sled or an orchestrator.

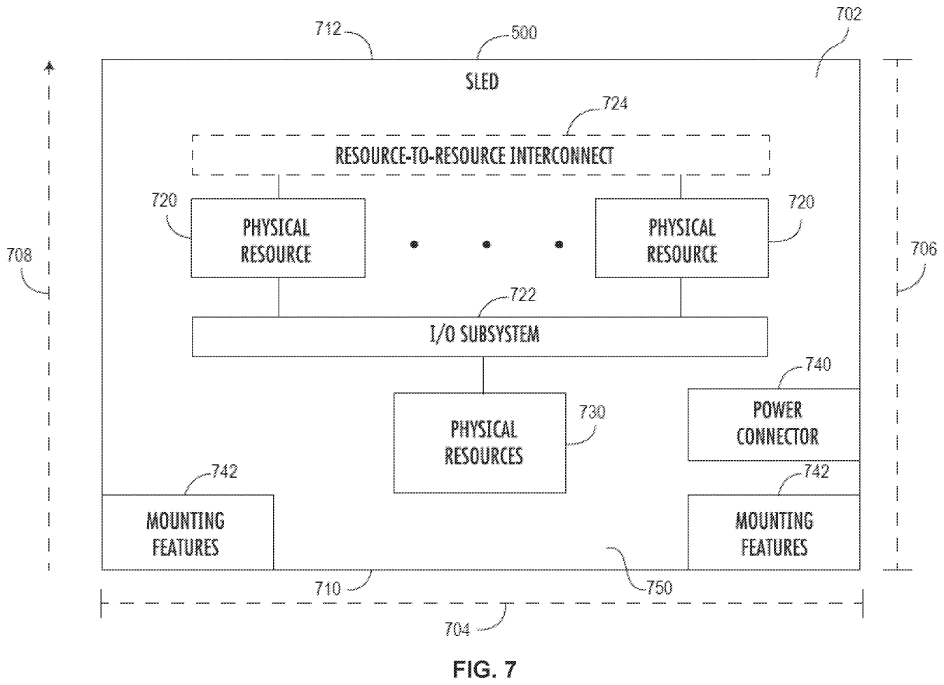

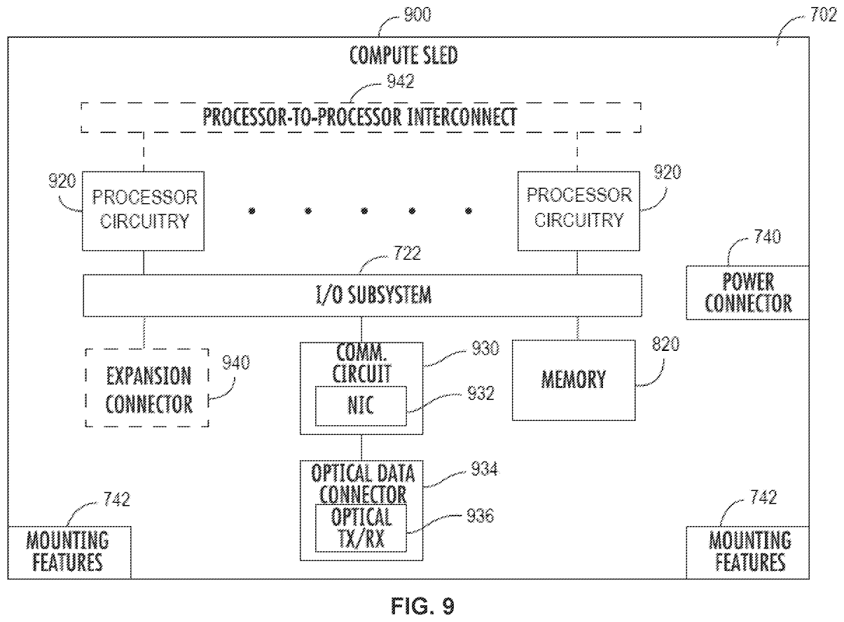

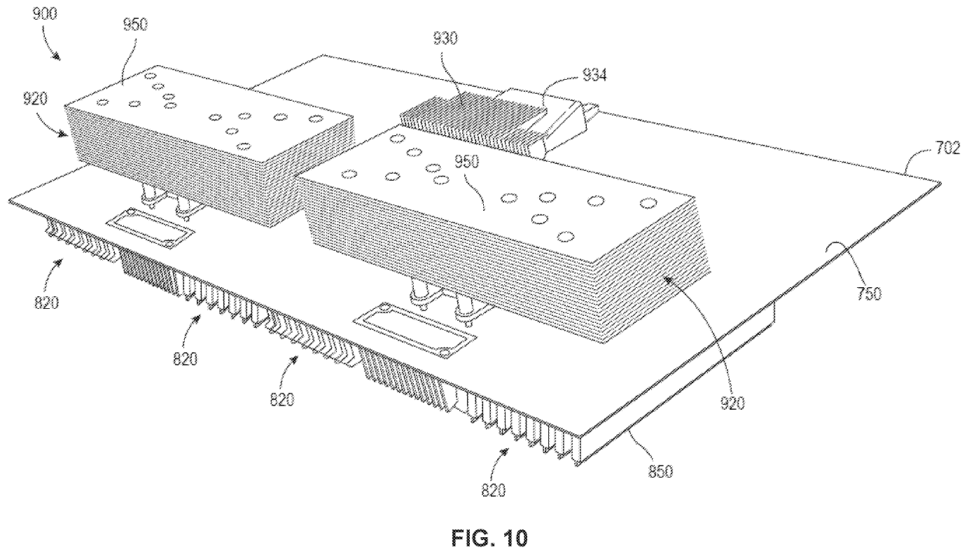

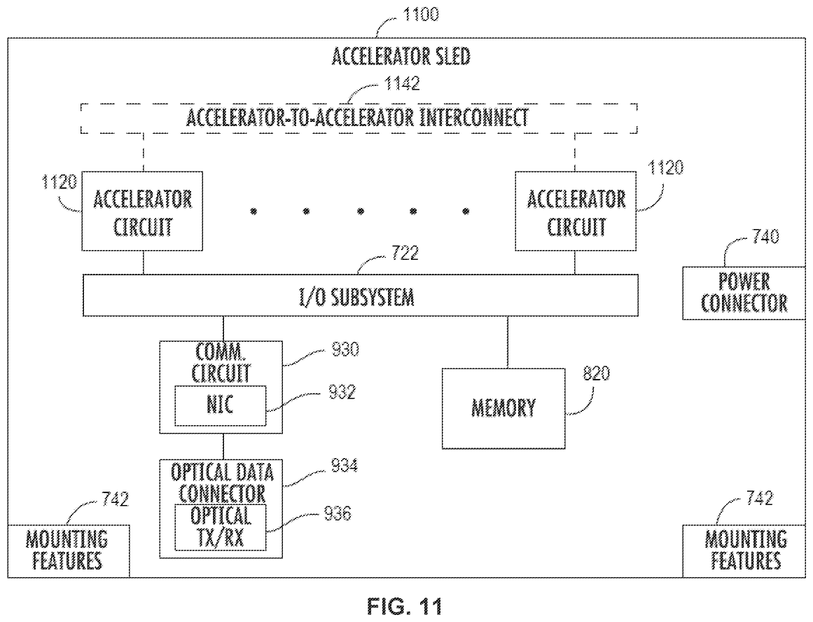

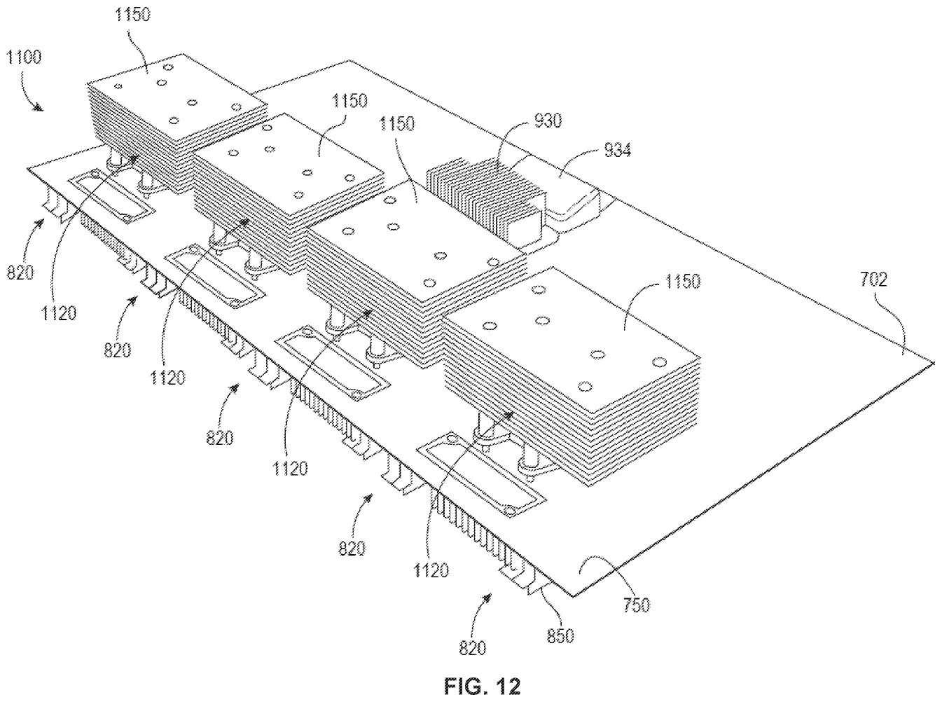

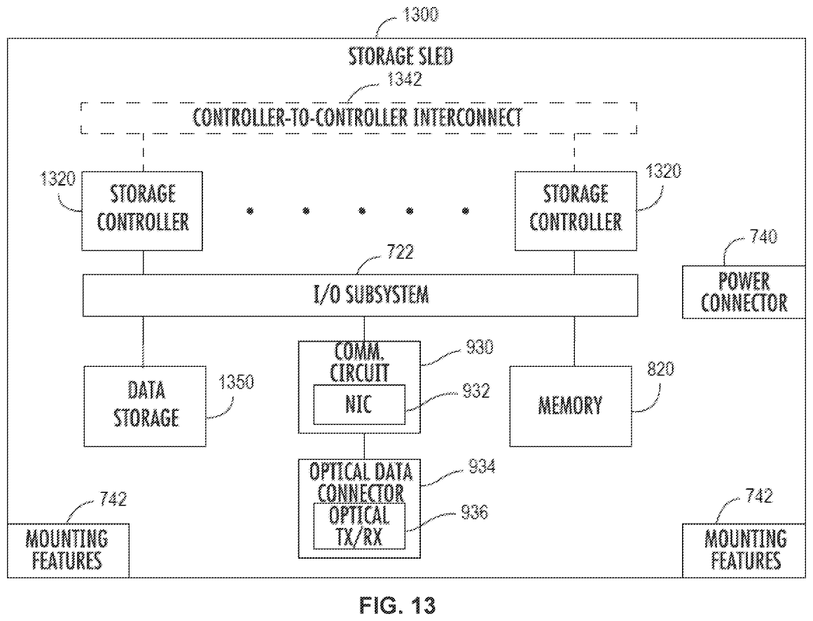

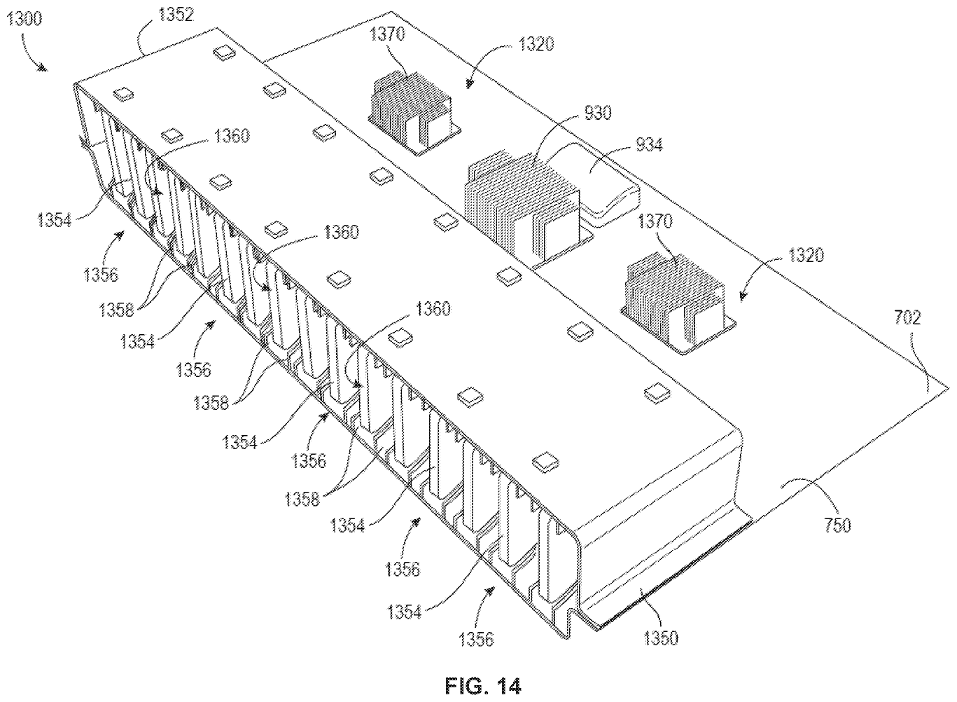

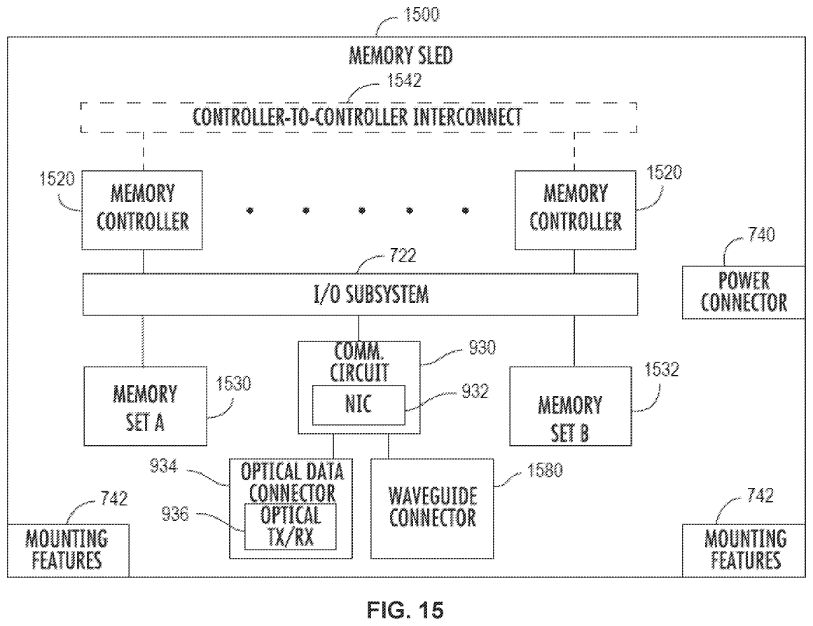

Referring now to FIG. 7, the sled 500, in the illustrative example, is configured to be mounted in a corresponding rack 340 of the data center 200 as discussed above. In some examples, a give sled 500 may be optimized or otherwise configured for performing particular tasks, such as compute tasks, acceleration tasks, data storage tasks, etc. For example, the sled 500 may be implemented as a compute sled 900 as discussed below in regard to FIGS. 9 and 10, an accelerator sled 1100 as discussed below in regard to FIGS. 11 and 12, a storage sled 1300 as discussed below in regard to FIGS. 13 and 14, or as a sled optimized or otherwise configured to perform other specialized tasks, such as a memory sled 1500, discussed below in regard to FIG. 15.

As discussed above, the illustrative sled 500 includes a chassis-less circuit board substrate 702, which supports various physical resources (e.g., electrical components) mounted thereon. It should be appreciated that the circuit board substrate 702 is “chassis-less” in that the sled 500 does not include a housing or enclosure. Rather, the chassis-less circuit board substrate 702 is open to the local environment. The chassis-less circuit board substrate 702 may be formed from any material capable of supporting the various electrical components mounted thereon. For example, in an illustrative example, the chassis-less circuit board substrate 702 is formed from an FR-4 glass-reinforced epoxy laminate material. Other materials may be used to form the chassis-less circuit board substrate 702 in other examples.

As discussed in more detail below, the chassis-less circuit board substrate 702 includes multiple features that improve the thermal cooling characteristics of the various electrical components mounted on the chassis-less circuit board substrate 702. As discussed, the chassis-less circuit board substrate 702 does not include a housing or enclosure, which may improve the airflow over the electrical components of the sled 500 by reducing those structures that may inhibit air flow. For example, because the chassis-less circuit board substrate 702 is not positioned in an individual housing or enclosure, there is no vertically-arranged backplane (e.g., a back plate of the chassis) attached to the chassis-less circuit board substrate 702, which could inhibit air flow across the electrical components. Additionally, the chassis-less circuit board substrate 702 has a geometric shape configured to reduce the length of the airflow path across the electrical components mounted to the chassis-less circuit board substrate 702. For example, the illustrative chassis-less circuit board substrate 702 has a width 704 that is greater than a depth 706 of the chassis-less circuit board substrate 702. In one particular example, the chassis-less circuit board substrate 702 has a width of about 21 inches and a depth of about 9 inches, compared to a typical server that has a width of about 17 inches and a depth of about 39 inches. As such, an airflow path 708 that extends from a front edge 710 of the chassis-less circuit board substrate 702 toward a rear edge 712 has a shorter distance relative to typical servers, which may improve the thermal cooling characteristics of the sled 500. Furthermore, although not illustrated in FIG. 7, the various physical resources mounted to the chassis-less circuit board substrate 702 in this example are mounted in corresponding locations such that no two substantively heat-producing electrical components shadow each other as discussed in more detail below. That is, no two electrical components, which produce appreciable heat during operation (i.e., greater than a nominal heat sufficient enough to adversely impact the cooling of another electrical component), are mounted to the chassis-less circuit board substrate 702 linearly in-line with each other along the direction of the airflow path 708 (i.e., along a direction extending from the front edge 710 toward the rear edge 712 of the chassis-less circuit board substrate 702). The placement and/or structure of the features may be suitable adapted when the electrical component(s) are being cooled via liquid (e.g., one phase or two phase immersion cooling).

As discussed above, the illustrative sled 500 includes one or more physical resources 720 mounted to a top side 750 of the chassis-less circuit board substrate 702. Although two physical resources 720 are shown in FIG. 7, it should be appreciated that the sled 500 may include one, two, or more physical resources 720 in other examples. The physical resources 720 may be implemented as any type of processor, controller, or other compute circuit capable of performing various tasks such as compute functions and/or controlling the functions of the sled 500 depending on, for example, the type or intended functionality of the sled 500. For example, as discussed in more detail below, the physical resources 720 may be implemented as high-performance processors in examples in which the sled 500 is implemented as a compute sled, as accelerator co-processors or circuits in examples in which the sled 500 is implemented as an accelerator sled, storage controllers in examples in which the sled 500 is implemented as a storage sled, or a set of memory devices in examples in which the sled 500 is implemented as a memory sled.

The sled 500 also includes one or more additional physical resources 730 mounted to the top side 750 of the chassis-less circuit board substrate 702. In the illustrative example, the additional physical resources include a network interface controller (NIC) as discussed in more detail below. Depending on the type and functionality of the sled 500, the physical resources 730 may include additional or other electrical components, circuits, and/or devices in other examples.

The physical resources 720 are communicatively coupled to the physical resources 730 via an input/output (I/O) subsystem 722. The I/O subsystem 722 may be implemented as circuitry and/or components to facilitate input/output operations with the physical resources 720, the physical resources 730, and/or other components of the sled 500. For example, the I/O subsystem 722 may be implemented as, or otherwise include, memory controller hubs, input/output control hubs, integrated sensor hubs, firmware devices, communication links (e.g., point-to-point links, bus links, wires, cables, waveguides, light guides, printed circuit board traces, etc.), and/or other components and subsystems to facilitate the input/output operations. In the illustrative example, the I/O subsystem 722 is implemented as, or otherwise includes, a double data rate 4 (DDR4) data bus or a DDR5 data bus.

In some examples, the sled 500 may also include a resource-to-resource interconnect 724. The resource-to-resource interconnect 724 may be implemented as any type of communication interconnect capable of facilitating resource-to-resource communications. In the illustrative example, the resource-to-resource interconnect 724 is implemented as a high-speed point-to-point interconnect (e.g., faster than the I/O subsystem 722). For example, the resource-to-resource interconnect 724 may be implemented as a QuickPath Interconnect (QPI), an UltraPath Interconnect (UPI), or other high-speed point-to-point interconnect dedicated to resource-to-resource communications.

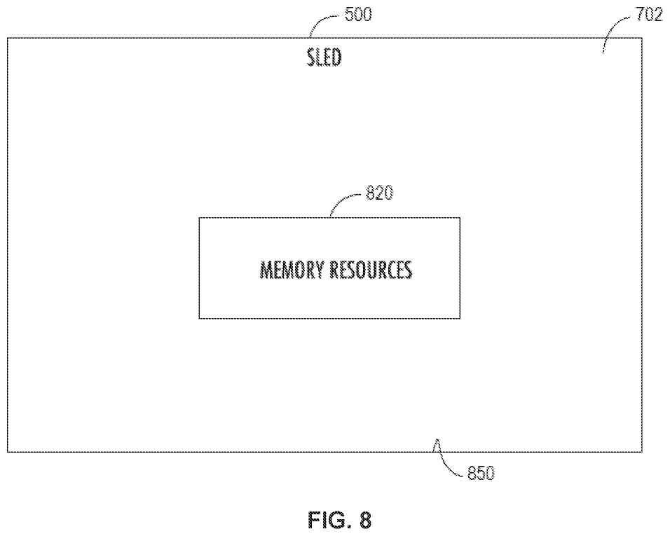

The sled 500 also includes a power connector 740 configured to mate with a corresponding power connector of the rack 340 when the sled 500 is mounted in the corresponding rack 340. The sled 500 receives power from a power supply of the rack 340 via the power connector 740 to supply power to the various electrical components of the sled 500. That is, the sled 500 does not include any local power supply (i.e., an on-board power supply) to provide power to the electrical components of the sled 500. The exclusion of a local or on-board power supply facilitates the reduction in the overall footprint of the chassis-less circuit board substrate 702, which may increase the thermal cooling characteristics of the various electrical components mounted on the chassis-less circuit board substrate 702 as discussed above. In some examples, voltage regulators are placed on a bottom side 850 (see FIG. 8) of the chassis-less circuit board substrate 702 directly opposite of processor circuitry 920 (see FIG. 9), and power is routed from the voltage regulators to the processor circuitry 920 by vias extending through the circuit board substrate 702. Such a configuration provides an increased thermal budget, additional current and/or voltage, and better voltage control relative to typical printed circuit boards in which processor power is delivered from a voltage regulator, in part, by printed circuit traces.

In some examples, the sled 500 may also include mounting features 742 configured to mate with a mounting arm, or other structure, of a robot to facilitate the placement of the sled 700 in a rack 340 by the robot. The mounting features 742 may be implemented as any type of physical structures that allow the robot to grasp the sled 500 without damaging the chassis-less circuit board substrate 702 or the electrical components mounted thereto. For example, in some examples, the mounting features 742 may be implemented as non-conductive pads attached to the chassis-less circuit board substrate 702. In other examples, the mounting features may be implemented as brackets, braces, or other similar structures attached to the chassis-less circuit board substrate 702. The particular number, shape, size, and/or make-up of the mounting feature 742 may depend on the design of the robot configured to manage the sled 500.

Referring now to FIG. 8, in addition to the physical resources 730 mounted on the top side 750 of the chassis-less circuit board substrate 702, the sled 500 also includes one or more memory devices 820 mounted to a bottom side 850 of the chassis-less circuit board substrate 702. That is, the chassis-less circuit board substrate 702 is implemented as a double-sided circuit board. The physical resources 720 are communicatively coupled to the memory devices 820 via the I/O subsystem 722. For example, the physical resources 720 and the memory devices 820 may be communicatively coupled by one or more vias extending through the chassis-less circuit board substrate 702. Different ones of the physical resources 720 may be communicatively coupled to different sets of one or more memory devices 820 in some examples. Alternatively, in other examples, different ones of the physical resources 720 may be communicatively coupled to the same ones of the memory devices 820.

The memory devices 820 may be implemented as any type of memory device capable of storing data for the physical resources 720 during operation of the sled 500, such as any type of volatile (e.g., dynamic random access memory (DRAM), etc.) or non-volatile memory. Volatile memory may be a storage medium that requires power to maintain the state of data stored by the medium. Non-limiting examples of volatile memory may include various types of random access memory (RAM), such as dynamic random access memory (DRAM) or static random access memory (SRAM). One particular type of DRAM that may be used in a memory module is synchronous dynamic random access memory (SDRAM). In particular examples, DRAM of a memory component may comply with a standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4. Such standards (and similar standards) may be referred to as DDR-based standards and communication interfaces of the storage devices that implement such standards may be referred to as DDR-based interfaces.

In one example, the memory device is a block addressable memory device, such as those based on NAND or NOR technologies. A memory device may also include next-generation nonvolatile devices, such as Intel 3D XPoint™ memory or other byte addressable write-in-place nonvolatile memory devices. In one example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory. The memory device may refer to the die itself and/or to a packaged memory product. In some examples, the memory device may include a transistor-less stackable cross point architecture in which memory cells sit at the intersection of word lines and bit lines and are individually addressable and in which bit storage is based on a change in bulk resistance.

Referring now to FIG. 9, in some examples, the sled 500 may be implemented as a compute sled 900. The compute sled 900 is optimized, or otherwise configured, to perform compute tasks. As discussed above, the compute sled 900 may rely on other sleds, such as acceleration sleds and/or storage sleds, to perform such compute tasks. The compute sled 900 includes various physical resources (e.g., electrical components) similar to the physical resources of the sled 500, which have been identified in FIG. 9 using the same reference numbers. The description of such components provided above in regard to FIGS. 7 and 8 applies to the corresponding components of the compute sled 900 and is not repeated herein for clarity of the description of the compute sled 900.

In the illustrative compute sled 900, the physical resources 720 include processor circuitry 920. Although only two blocks of processor circuitry 920 are shown in FIG. 9, it should be appreciated that the compute sled 900 may include additional processor circuits 920 in other examples. Illustratively, the processor circuitry 920 corresponds to high-performance processors 920 and may be configured to operate at a relatively high power rating. Although the high-performance processor circuitry 920 generates additional heat operating at power ratings greater than typical processors (which operate at around 155-230 W), the enhanced thermal cooling characteristics of the chassis-less circuit board substrate 702 discussed above facilitate the higher power operation. For example, in the illustrative example, the processor circuitry 920 is configured to operate at a power rating of at least 250 W. In some examples, the processor circuitry 920 may be configured to operate at a power rating of at least 350 W.

In some examples, the compute sled 900 may also include a processor-to-processor interconnect 942. Similar to the resource-to-resource interconnect 724 of the sled 500 discussed above, the processor-to-processor interconnect 942 may be implemented as any type of communication interconnect capable of facilitating processor-to-processor interconnect 942 communications. In the illustrative example, the processor-to-processor interconnect 942 is implemented as a high-speed point-to-point interconnect (e.g., faster than the I/O subsystem 722). For example, the processor-to-processor interconnect 942 may be implemented as a QuickPath Interconnect (QPI), an UltraPath Interconnect (UPI), or other high-speed point-to-point interconnect dedicated to processor-to-processor communications.

The compute sled 900 also includes a communication circuit 930. The illustrative communication circuit 930 includes a network interface controller (NIC) 932, which may also be referred to as a host fabric interface (HFI). The NIC 932 may be implemented as, or otherwise include, any type of integrated circuit, discrete circuits, controller chips, chipsets, add-in-boards, daughtercards, network interface cards, or other devices that may be used by the compute sled 900 to connect with another compute device (e.g., with other sleds 500). In some examples, the NIC 932 may be implemented as part of a system-on-a-chip (SoC) that includes one or more processors, or included on a multichip package that also contains one or more processors. In some examples, the NIC 932 may include a local processor (not shown) and/or a local memory (not shown) that are both local to the NIC 932. In such examples, the local processor of the NIC 932 may be capable of performing one or more of the functions of the processor circuitry 920. Additionally or alternatively, in such examples, the local memory of the NIC 932 may be integrated into one or more components of the compute sled at the board level, socket level, chip level, and/or other levels.

The communication circuit 930 is communicatively coupled to an optical data connector 934. The optical data connector 934 is configured to mate with a corresponding optical data connector of the rack 340 when the compute sled 900 is mounted in the rack 340. Illustratively, the optical data connector 934 includes a plurality of optical fibers which lead from a mating surface of the optical data connector 934 to an optical transceiver 936. The optical transceiver 936 is configured to convert incoming optical signals from the rack-side optical data connector to electrical signals and to convert electrical signals to outgoing optical signals to the rack-side optical data connector. Although shown as forming part of the optical data connector 934 in the illustrative example, the optical transceiver 936 may form a portion of the communication circuit 930 in other examples.

In some examples, the compute sled 900 may also include an expansion connector 940. In such examples, the expansion connector 940 is configured to mate with a corresponding connector of an expansion chassis-less circuit board substrate to provide additional physical resources to the compute sled 900. The additional physical resources may be used, for example, by the processor circuitry 920 during operation of the compute sled 900. The expansion chassis-less circuit board substrate may be substantially similar to the chassis-less circuit board substrate 702 discussed above and may include various electrical components mounted thereto. The particular electrical components mounted to the expansion chassis-less circuit board substrate may depend on the intended functionality of the expansion chassis-less circuit board substrate. For example, the expansion chassis-less circuit board substrate may provide additional compute resources, memory resources, and/or storage resources. As such, the additional physical resources of the expansion chassis-less circuit board substrate may include, but is not limited to, processors, memory devices, storage devices, and/or accelerator circuits including, for example, field programmable gate arrays (FPGA), application-specific integrated circuits (ASICs), security co-processors, graphics processing units (GPUs), machine learning circuits, or other specialized processors, controllers, devices, and/or circuits.

Referring now to FIG. 10, an illustrative example of the compute sled 900 is shown. As shown, the processor circuitry 920, communication circuit 930, and optical data connector 934 are mounted to the top side 750 of the chassis-less circuit board substrate 702. Any suitable attachment or mounting technology may be used to mount the physical resources of the compute sled 900 to the chassis-less circuit board substrate 702. For example, the various physical resources may be mounted in corresponding sockets (e.g., a processor socket), holders, or brackets. In some cases, some of the electrical components may be directly mounted to the chassis-less circuit board substrate 702 via soldering or similar techniques.

As discussed above, the separate processor circuitry 920 and the communication circuit 930 are mounted to the top side 750 of the chassis-less circuit board substrate 702 such that no two heat-producing, electrical components shadow each other. In the illustrative example, the processor circuitry 920 and the communication circuit 930 are mounted in corresponding locations on the top side 750 of the chassis-less circuit board substrate 702 such that no two of those physical resources are linearly in-line with others along the direction of the airflow path 708. It should be appreciated that, although the optical data connector 934 is in-line with the communication circuit 930, the optical data connector 934 produces no or nominal heat during operation.

The memory devices 820 of the compute sled 900 are mounted to the bottom side 850 of the of the chassis-less circuit board substrate 702 as discussed above in regard to the sled 500. Although mounted to the bottom side 850, the memory devices 820 are communicatively coupled to the processor circuitry 920 located on the top side 750 via the I/O subsystem 722. Because the chassis-less circuit board substrate 702 is implemented as a double-sided circuit board, the memory devices 820 and the processor circuitry 920 may be communicatively coupled by one or more vias, connectors, or other mechanisms extending through the chassis-less circuit board substrate 702. Different processor circuitry 920 (e.g., different processors) may be communicatively coupled to a different set of one or more memory devices 820 in some examples. Alternatively, in other examples, different processor circuitry 920 (e.g., different processors) may be communicatively coupled to the same ones of the memory devices 820. In some examples, the memory devices 820 may be mounted to one or more memory mezzanines on the bottom side of the chassis-less circuit board substrate 702 and may interconnect with a corresponding processor circuitry 920 through a ball-grid array.

Different processor circuitry 920 (e.g., different processors) include and/or is associated with corresponding heatsinks 950 secured thereto. Due to the mounting of the memory devices 820 to the bottom side 850 of the chassis-less circuit board substrate 702 (as well as the vertical spacing of the sleds 500 in the corresponding rack 340), the top side 750 of the chassis-less circuit board substrate 702 includes additional “free” area or space that facilitates the use of heatsinks 950 having a larger size relative to traditional heatsinks used in typical servers. Additionally, due to the improved thermal cooling characteristics of the chassis-less circuit board substrate 702, none of the processor heatsinks 950 include cooling fans attached thereto. That is, the heatsinks 950 may be fan-less heatsinks. In some examples, the heatsinks 950 mounted atop the processor circuitry 920 may overlap with the heatsink attached to the communication circuit 930 in the direction of the airflow path 708 due to their increased size, as illustratively suggested by FIG. 10.

Referring now to FIG. 11, in some examples, the sled 500 may be implemented as an accelerator sled 1100. The accelerator sled 1100 is configured, to perform specialized compute tasks, such as machine learning, encryption, hashing, or other computational-intensive task. In some examples, for example, a compute sled 900 may offload tasks to the accelerator sled 1100 during operation. The accelerator sled 1100 includes various components similar to components of the sled 500 and/or the compute sled 900, which have been identified in FIG. 11 using the same reference numbers. The description of such components provided above in regard to FIGS. 7, 8, and 9 apply to the corresponding components of the accelerator sled 1100 and is not repeated herein for clarity of the description of the accelerator sled 1100.

In the illustrative accelerator sled 1100, the physical resources 720 include accelerator circuits 1120. Although only two accelerator circuits 1120 are shown in FIG. 11, it should be appreciated that the accelerator sled 1100 may include additional accelerator circuits 1120 in other examples. For example, as shown in FIG. 12, the accelerator sled 1100 may include four accelerator circuits 1120. The accelerator circuits 1120 may be implemented as any type of processor, co-processor, compute circuit, or other device capable of performing compute or processing operations. For example, the accelerator circuits 1120 may be implemented as, for example, field programmable gate arrays (FPGA), application-specific integrated circuits (ASICs), security co-processors, graphics processing units (GPUs), neuromorphic processor units, quantum computers, machine learning circuits, or other specialized processors, controllers, devices, and/or circuits.

In some examples, the accelerator sled 1100 may also include an accelerator-to-accelerator interconnect 1142. Similar to the resource-to-resource interconnect 724 of the sled 700 discussed above, the accelerator-to-accelerator interconnect 1142 may be implemented as any type of communication interconnect capable of facilitating accelerator-to-accelerator communications. In the illustrative example, the accelerator-to-accelerator interconnect 1142 is implemented as a high-speed point-to-point interconnect (e.g., faster than the I/O subsystem 722). For example, the accelerator-to-accelerator interconnect 1142 may be implemented as a QuickPath Interconnect (QPI), an UltraPath Interconnect (UPI), or other high-speed point-to-point interconnect dedicated to processor-to-processor communications. In some examples, the accelerator circuits 1120 may be daisy-chained with a primary accelerator circuit 1120 connected to the NIC 932 and memory 820 through the I/O subsystem 722 and a secondary accelerator circuit 1120 connected to the NIC 932 and memory 820 through a primary accelerator circuit 1120.

Referring now to FIG. 12, an illustrative example of the accelerator sled 1100 is shown. As discussed above, the accelerator circuits 1120, the communication circuit 930, and the optical data connector 934 are mounted to the top side 750 of the chassis-less circuit board substrate 702. Again, the individual accelerator circuits 1120 and communication circuit 930 are mounted to the top side 750 of the chassis-less circuit board substrate 702 such that no two heat-producing, electrical components shadow each other as discussed above. The memory devices 820 of the accelerator sled 1100 are mounted to the bottom side 850 of the of the chassis-less circuit board substrate 702 as discussed above in regard to the sled 700. Although mounted to the bottom side 850, the memory devices 820 are communicatively coupled to the accelerator circuits 1120 located on the top side 750 via the I/O subsystem 722 (e.g., through vias). Further, the accelerator circuits 1120 may include and/or be associated with a heatsink 1150 that is larger than a traditional heatsink used in a server. As discussed above with reference to the heatsinks 950 of FIG. 9, the heatsinks 1150 may be larger than traditional heatsinks because of the “free” area provided by the memory resources 820 being located on the bottom side 850 of the chassis-less circuit board substrate 702 rather than on the top side 750.

Referring now to FIG. 13, in some examples, the sled 500 may be implemented as a storage sled 1300. The storage sled 1300 is configured, to store data in a data storage 1350 local to the storage sled 1300. For example, during operation, a compute sled 900 or an accelerator sled 1100 may store and retrieve data from the data storage 1350 of the storage sled 1300. The storage sled 1300 includes various components similar to components of the sled 500 and/or the compute sled 900, which have been identified in FIG. 13 using the same reference numbers. The description of such components provided above in regard to FIGS. 7, 8, and 9 apply to the corresponding components of the storage sled 1300 and is not repeated herein for clarity of the description of the storage sled 1300.

In the illustrative storage sled 1300, the physical resources 720 includes storage controllers 1320. Although only two storage controllers 1320 are shown in FIG. 13, it should be appreciated that the storage sled 1300 may include additional storage controllers 1320 in other examples. The storage controllers 1320 may be implemented as any type of processor, controller, or control circuit capable of controlling the storage and retrieval of data into the data storage 1350 based on requests received via the communication circuit 930. In the illustrative example, the storage controllers 1320 are implemented as relatively low-power processors or controllers. For example, in some examples, the storage controllers 1320 may be configured to operate at a power rating of about 75 watts.

In some examples, the storage sled 1300 may also include a controller-to-controller interconnect 1342. Similar to the resource-to-resource interconnect 724 of the sled 500 discussed above, the controller-to-controller interconnect 1342 may be implemented as any type of communication interconnect capable of facilitating controller-to-controller communications. In the illustrative example, the controller-to-controller interconnect 1342 is implemented as a high-speed point-to-point interconnect (e.g., faster than the I/O subsystem 722). For example, the controller-to-controller interconnect 1342 may be implemented as a QuickPath Interconnect (QPI), an UltraPath Interconnect (UPI), or other high-speed point-to-point interconnect dedicated to processor-to-processor communications.

Referring now to FIG. 14, an illustrative example of the storage sled 1300 is shown. In the illustrative example, the data storage 1350 is implemented as, or otherwise includes, a storage cage 1352 configured to house one or more solid state drives (SSDs) 1354. To do so, the storage cage 1352 includes a number of mounting slots 1356, which are configured to receive corresponding solid state drives 1354. The mounting slots 1356 include a number of drive guides 1358 that cooperate to define an access opening 1360 of the corresponding mounting slot 1356. The storage cage 1352 is secured to the chassis-less circuit board substrate 702 such that the access openings face away from (i.e., toward the front of) the chassis-less circuit board substrate 702. As such, solid state drives 1354 are accessible while the storage sled 1300 is mounted in a corresponding rack 304. For example, a solid state drive 1354 may be swapped out of a rack 340 (e.g., via a robot) while the storage sled 1300 remains mounted in the corresponding rack 340.

The storage cage 1352 illustratively includes sixteen mounting slots 1356 and is capable of mounting and storing sixteen solid state drives 1354. The storage cage 1352 may be configured to store additional or fewer solid state drives 1354 in other examples. Additionally, in the illustrative example, the solid state drives are mounted vertically in the storage cage 1352, but may be mounted in the storage cage 1352 in a different orientation in other examples. A given solid state drive 1354 may be implemented as any type of data storage device capable of storing long term data. To do so, the solid state drives 1354 may include volatile and non-volatile memory devices discussed above.

As shown in FIG. 14, the storage controllers 1320, the communication circuit 930, and the optical data connector 934 are illustratively mounted to the top side 750 of the chassis-less circuit board substrate 702. Again, as discussed above, any suitable attachment or mounting technology may be used to mount the electrical components of the storage sled 1300 to the chassis-less circuit board substrate 702 including, for example, sockets (e.g., a processor socket), holders, brackets, soldered connections, and/or other mounting or securing techniques.

As discussed above, the individual storage controllers 1320 and the communication circuit 930 are mounted to the top side 750 of the chassis-less circuit board substrate 702 such that no two heat-producing, electrical components shadow each other. For example, the storage controllers 1320 and the communication circuit 930 are mounted in corresponding locations on the top side 750 of the chassis-less circuit board substrate 702 such that no two of those electrical components are linearly in-line with each other along the direction of the airflow path 708.

The memory devices 820 (not shown in FIG. 14) of the storage sled 1300 are mounted to the bottom side 850 (not shown in FIG. 14) of the chassis-less circuit board substrate 702 as discussed above in regard to the sled 500. Although mounted to the bottom side 850, the memory devices 820 are communicatively coupled to the storage controllers 1320 located on the top side 750 via the I/O subsystem 722. Again, because the chassis-less circuit board substrate 702 is implemented as a double-sided circuit board, the memory devices 820 and the storage controllers 1320 may be communicatively coupled by one or more vias, connectors, or other mechanisms extending through the chassis-less circuit board substrate 702. The storage controllers 1320 include and/or are associated with a heatsink 1370 secured thereto. As discussed above, due to the improved thermal cooling characteristics of the chassis-less circuit board substrate 702 of the storage sled 1300, none of the heatsinks 1370 include cooling fans attached thereto. That is, the heatsinks 1370 may be fan-less heatsinks.

Referring now to FIG. 15, in some examples, the sled 500 may be implemented as a memory sled 1500. The storage sled 1500 is optimized, or otherwise configured, to provide other sleds 500 (e.g., compute sleds 900, accelerator sleds 1100, etc.) with access to a pool of memory (e.g., in two or more sets 1530, 1532 of memory devices 820) local to the memory sled 1300. For example, during operation, a compute sled 900 or an accelerator sled 1100 may remotely write to and/or read from one or more of the memory sets 1530, 1532 of the memory sled 1300 using a logical address space that maps to physical addresses in the memory sets 1530, 1532. The memory sled 1500 includes various components similar to components of the sled 500 and/or the compute sled 900, which have been identified in FIG. 15 using the same reference numbers. The description of such components provided above in regard to FIGS. 7, 8, and 9 apply to the corresponding components of the memory sled 1500 and is not repeated herein for clarity of the description of the memory sled 1500.

In the illustrative memory sled 1500, the physical resources 720 include memory controllers 1520. Although only two memory controllers 1520 are shown in FIG. 15, it should be appreciated that the memory sled 1500 may include additional memory controllers 1520 in other examples. The memory controllers 1520 may be implemented as any type of processor, controller, or control circuit capable of controlling the writing and reading of data into the memory sets 1530, 1532 based on requests received via the communication circuit 930. In the illustrative example, the memory controllers 1520 are connected to corresponding memory sets 1530, 1532 to write to and read from memory devices 820 (not shown) within the corresponding memory set 1530, 1532 and enforce any permissions (e.g., read, write, etc.) associated with sled 500 that has sent a request to the memory sled 1500 to perform a memory access operation (e.g., read or write).

In some examples, the memory sled 1500 may also include a controller-to-controller interconnect 1542. Similar to the resource-to-resource interconnect 724 of the sled 500 discussed above, the controller-to-controller interconnect 1542 may be implemented as any type of communication interconnect capable of facilitating controller-to-controller communications. In the illustrative example, the controller-to-controller interconnect 1542 is implemented as a high-speed point-to-point interconnect (e.g., faster than the I/O subsystem 722). For example, the controller-to-controller interconnect 1542 may be implemented as a QuickPath Interconnect (QPI), an UltraPath Interconnect (UPI), or other high-speed point-to-point interconnect dedicated to processor-to-processor communications. As such, in some examples, a memory controller 1520 may access, through the controller-to-controller interconnect 1542, memory that is within the memory set 1532 associated with another memory controller 1520. In some examples, a scalable memory controller is made of multiple smaller memory controllers, referred to herein as “chiplets”, on a memory sled (e.g., the memory sled 1500). The chiplets may be interconnected (e.g., using EMIB (Embedded Multi-Die Interconnect Bridge) technology). The combined chiplet memory controller may scale up to a relatively large number of memory controllers and I/O ports, (e.g., up to 16 memory channels). In some examples, the memory controllers 1520 may implement a memory interleave (e.g., one memory address is mapped to the memory set 1530, the next memory address is mapped to the memory set 1532, and the third address is mapped to the memory set 1530, etc.). The interleaving may be managed within the memory controllers 1520, or from CPU sockets (e.g., of the compute sled 900) across network links to the memory sets 1530, 1532, and may improve the latency associated with performing memory access operations as compared to accessing contiguous memory addresses from the same memory device.

Further, in some examples, the memory sled 1500 may be connected to one or more other sleds 500 (e.g., in the same rack 340 or an adjacent rack 340) through a waveguide, using the waveguide connector 1580. In the illustrative example, the waveguides are 74 millimeter waveguides that provide 16 Rx (i.e., receive) lanes and 16 Tx (i.e., transmit) lanes. Different ones of the lanes, in the illustrative example, are either 16 GHz or 32 GHz. In other examples, the frequencies may be different. Using a waveguide may provide high throughput access to the memory pool (e.g., the memory sets 1530, 1532) to another sled (e.g., a sled 500 in the same rack 340 or an adjacent rack 340 as the memory sled 1500) without adding to the load on the optical data connector 934.

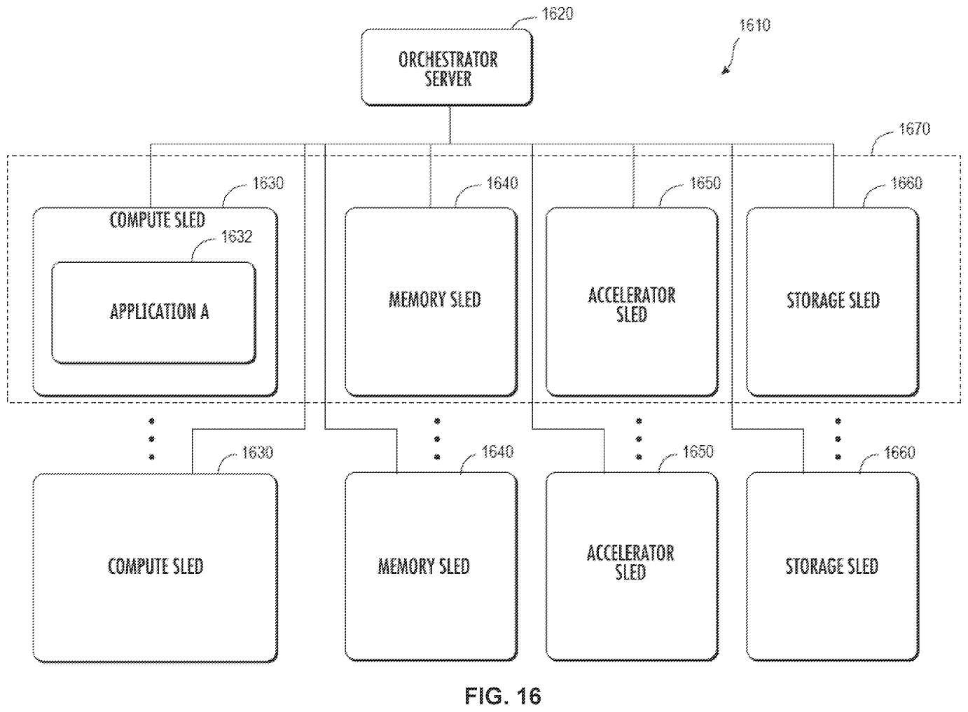

Referring now to FIG. 16, a system for executing one or more workloads (e.g., applications) may be implemented in accordance with the data center 200. In the illustrative example, the system 1610 includes an orchestrator server 1620, which may be implemented as a managed node including a compute device (e.g., processor circuitry 920 on a compute sled 900) executing management software (e.g., a cloud operating environment, such as OpenStack) that is communicatively coupled to multiple sleds 500 including a large number of compute sleds 1630 (e.g., similar to the compute sled 900), memory sleds 1640 (e.g., similar to the memory sled 1500), accelerator sleds 1650 (e.g., similar to the memory sled 1000), and storage sleds 1660 (e.g., similar to the storage sled 1300). One or more of the sleds 1630, 1640, 1650, 1660 may be grouped into a managed node 1670, such as by the orchestrator server 1620, to collectively perform a workload (e.g., an application 1632 executed in a virtual machine or in a container). The managed node 1670 may be implemented as an assembly of physical resources 720, such as processor circuitry 920, memory resources 820, accelerator circuits 1120, or data storage 1350, from the same or different sleds 500. Further, the managed node may be established, defined, or “spun up” by the orchestrator server 1620 at the time a workload is to be assigned to the managed node or at any other time, and may exist regardless of whether any workloads are presently assigned to the managed node. In the illustrative example, the orchestrator server 1620 may selectively allocate and/or deallocate physical resources 720 from the sleds 500 and/or add or remove one or more sleds 500 from the managed node 1670 as a function of quality of service (QoS) targets (e.g., a target throughput, a target latency, a target number of instructions per second, etc.) associated with a service level agreement for the workload (e.g., the application 1632). In doing so, the orchestrator server 1620 may receive telemetry data indicative of performance conditions (e.g., throughput, latency, instructions per second, etc.) in different ones of the sleds 500 of the managed node 1670 and compare the telemetry data to the quality of service targets to determine whether the quality of service targets are being satisfied. The orchestrator server 1620 may additionally determine whether one or more physical resources may be deallocated from the managed node 1670 while still satisfying the QoS targets, thereby freeing up those physical resources for use in another managed node (e.g., to execute a different workload). Alternatively, if the QoS targets are not presently satisfied, the orchestrator server 1620 may determine to dynamically allocate additional physical resources to assist in the execution of the workload (e.g., the application 1632) while the workload is executing. Similarly, the orchestrator server 1620 may determine to dynamically deallocate physical resources from a managed node if the orchestrator server 1620 determines that deallocating the physical resource would result in QoS targets still being met.

Additionally, in some examples, the orchestrator server 1620 may identify trends in the resource utilization of the workload (e.g., the application 1632), such as by identifying phases of execution (e.g., time periods in which different operations, having different resource utilizations characteristics, are performed) of the workload (e.g., the application 1632) and pre-emptively identifying available resources in the data center 200 and allocating them to the managed node 1670 (e.g., within a predefined time period of the associated phase beginning). In some examples, the orchestrator server 1620 may model performance based on various latencies and a distribution scheme to place workloads among compute sleds and other resources (e.g., accelerator sleds, memory sleds, storage sleds) in the data center 200. For example, the orchestrator server 1620 may utilize a model that accounts for the performance of resources on the sleds 500 (e.g., FPGA performance, memory access latency, etc.) and the performance (e.g., congestion, latency, bandwidth) of the path through the network to the resource (e.g., FPGA). As such, the orchestrator server 1620 may determine which resource(s) should be used with which workloads based on the total latency associated with different potential resource(s) available in the data center 200 (e.g., the latency associated with the performance of the resource itself in addition to the latency associated with the path through the network between the compute sled executing the workload and the sled 500 on which the resource is located).

In some examples, the orchestrator server 1620 may generate a map of heat generation in the data center 200 using telemetry data (e.g., temperatures, fan speeds, etc.) reported from the sleds 500 and allocate resources to managed nodes as a function of the map of heat generation and predicted heat generation associated with different workloads, to maintain a target temperature and heat distribution in the data center 200. Additionally or alternatively, in some examples, the orchestrator server 1620 may organize received telemetry data into a hierarchical model that is indicative of a relationship between the managed nodes (e.g., a spatial relationship such as the physical locations of the resources of the managed nodes within the data center 200 and/or a functional relationship, such as groupings of the managed nodes by the customers the managed nodes provide services for, the types of functions typically performed by the managed nodes, managed nodes that typically share or exchange workloads among each other, etc.). Based on differences in the physical locations and resources in the managed nodes, a given workload may exhibit different resource utilizations (e.g., cause a different internal temperature, use a different percentage of processor or memory capacity) across the resources of different managed nodes. The orchestrator server 1620 may determine the differences based on the telemetry data stored in the hierarchical model and factor the differences into a prediction of future resource utilization of a workload if the workload is reassigned from one managed node to another managed node, to accurately balance resource utilization in the data center 200. In some examples, the orchestrator server 1620 may identify patterns in resource utilization phases of the workloads and use the patterns to predict future resource utilization of the workloads.

To reduce the computational load on the orchestrator server 1620 and the data transfer load on the network, in some examples, the orchestrator server 1620 may send self-test information to the sleds 500 to enable a given sled 500 to locally (e.g., on the sled 500) determine whether telemetry data generated by the sled 500 satisfies one or more conditions (e.g., an available capacity that satisfies a predefined threshold, a temperature that satisfies a predefined threshold, etc.). The given sled 500 may then report back a simplified result (e.g., yes or no) to the orchestrator server 1620, which the orchestrator server 1620 may utilize in determining the allocation of resources to managed nodes.

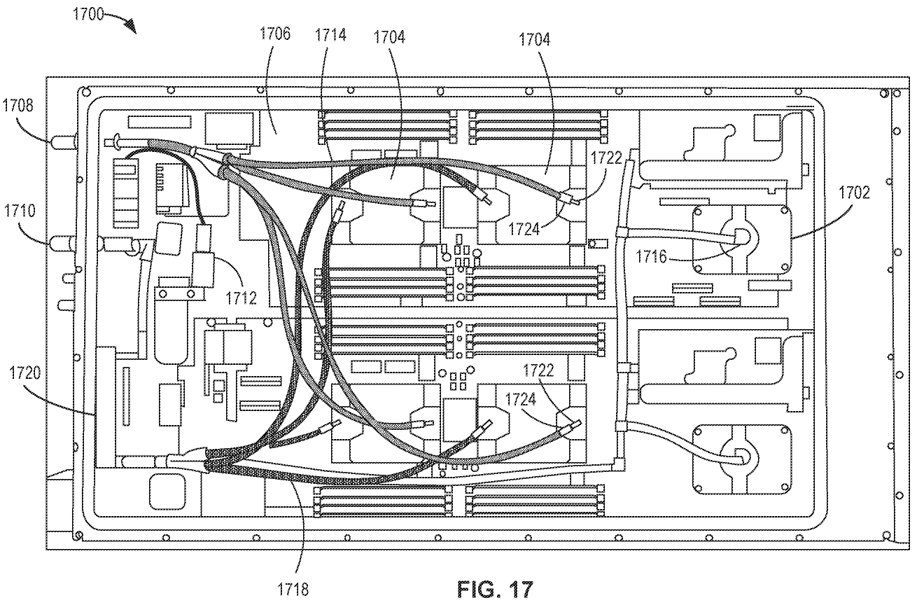

FIG. 17 illustrates a cooling system (e.g., a liquid cooling system) 1700 in which examples disclosed herein may be implemented. In FIG. 17, the cooling system 1700 cools one or more devices directly (e.g., by directing liquid to a surface of a processor chip 1702 and/or an associated circuit board 1706) and/or indirectly (e.g., by directing the liquid to one or more cold plates 1704 thermally coupled to a surface of a processor chip 1702 and/or an associated circuit board 1706).

In FIG. 17, the cooling system 1700 includes a fluid inlet 1708 and a fluid outlet 1710 through which liquid can enter and exit the cooling system 1700, respectively. Further, the cooling system 1700 includes a pump 1712 that operates to control the flow of fluid between the fluid inlet 1708 and the fluid outlet 1710. For instance, operation of the pump 1712 causes liquid to flow from the fluid inlet 1708 to the cold plates 1704 via first tubes (e.g. first conduit) 1714. In FIG. 17, the liquid from the first tubes 1714 cools the cold plate 1704 to cool an area of the underlying circuit board 1706. Further, liquid flows to a shower head 1716 proximate the processor chip 1702. In some cases, the liquid flows from the shower head 1716 directly onto a surface of the processor chip 1702 to facilitate cooling thereof. In FIG. 17, after the liquid is used to draw heat from the cold plates 1704 and/or the processor chip 1702, the heated liquid flows to the fluid outlet 1710 via second tubes (e.g., second conduit) 1718. In this instance, the liquid passes through a heat exchanger 1720 before reaching the fluid outlet 1710.

In FIG. 17, the tubes 1714, 1718 are connected (e.g., fluidly connected) to respective ones of the cold plates 1704 at connectors (e.g., fittings, barb fittings) 1722. For instance, end portions of the tubes 1714, 1718 can be stretched around respective ends of the connectors 1722 to fluidly couple the tubes 1714, 1718 to the connectors 1722. In this instance, to hold the tubes 1714, 1718 to the connectors 1722 and/or to prevent decoupling therebetween, crimps 1724 are placed at the end portions of the tubes 1714, 1718 and tightened to a desired cross-sectional size (e.g., less than or equal to a cross-sectional size of the tubes 1714, 1718 and/or the connectors 1722). In some instances, the crimps 1724 reduce hoop stress at the end portions of the tubes 1714, 1718 which may result from stretching of the tubes 1714, 1718 around the connectors 1722. In some such instances, by reducing the hoop stress caused by stretching of the tubes 1714, 1718, the crimps 1724 may reduce a likelihood of rupturing at the end portions of the tubes 1714, 1718.

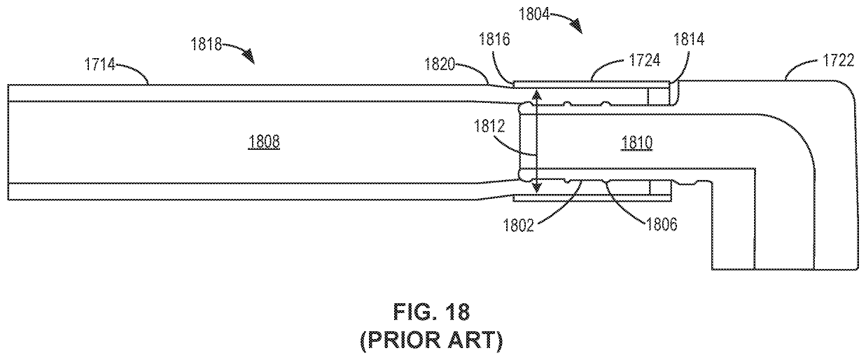

FIG. 18 illustrates a cross-sectional view of one of the tubes 1714 of FIG. 17 coupled to a respective one of the connectors 1722 of FIG. 17. The structure of the connector 1722 shown in FIG. 18 is for purposes of explanation, and other designs and/or structures for the connector 1722 are possible. In FIG. 17, a barbed portion 1802 of the connector 1722 is disposed in and/or surrounded by an end portion (e.g., a clamped portion, a crimped portion) 1804 of the tube 1714. In this instance, the barbed portion 1802 includes ridges or barbs 1806 that extend circumferentially along a surface of the barbed portion 1802, where the ridges 1806 facilitate retention of the end portion 1804 on the barbed portion 1802 (e.g., by preventing the end portion 1804 from sliding off of the barbed portion 1802). In this instance, the tube 1714 is fluidly coupled to the connector 1722 such that fluid (e.g., liquid and/or air) can flow between a first fluid path 1808 defined in the tube 1714 and a second fluid path 1810 defined in the connector 1722.

In FIG. 18, one of the crimps 1724 is used to clamp and/or tighten the end portion 1804 of the tube 1714 onto the barbed portion 1802 of the connector 1722. In this instance, the crimp 1724 has a circular cross-section, and an inner diameter 1812 of the crimp 1724 is substantially constant (e.g., not increasing or decreasing) along a longitudinal length between first and second ends 1814, 1816 of the crimp 1724. In FIG. 18, the crimp 1724 is positioned around the end portion 1804 of the tube 1714 and tightened to a desired cross-sectional size (e.g., less than a cross-sectional size of an uncrimped portion 1818 of the tube 1714). In this case, the crimp 1724 sealably couples an inner surface of the end portion 1804 to an outer surface of the barbed portion 1802 to restrict and/or prevent leakage of fluid from the tube 1714 and/or the connector 1722. In some instances, the crimp 1724 may, by compressing the end portion 1804 of the tube 1714, reduce a hoop stress in the end portion 1804 and, thus, prevent and/or reduce rupturing in the end portion 1804.

However, in some instances, tightening of the crimp 1724 onto the end portion 1804 results in stress at a surface of the uncrimped portion 1818 of the tube 1744. In particular, the stress may be concentrated at an example location 1820 of the tube 1714 at which the cross-sectional area of the tube 1714 begins to decrease from the uncrimped portion 1818 to the end portion 1804 of the tube 1714. In some instances, the stress at the location 1820 of the tube 1714 may cause creep in the tube 1714 and/or may result in failure (e.g., rupture) of the tube 1714.

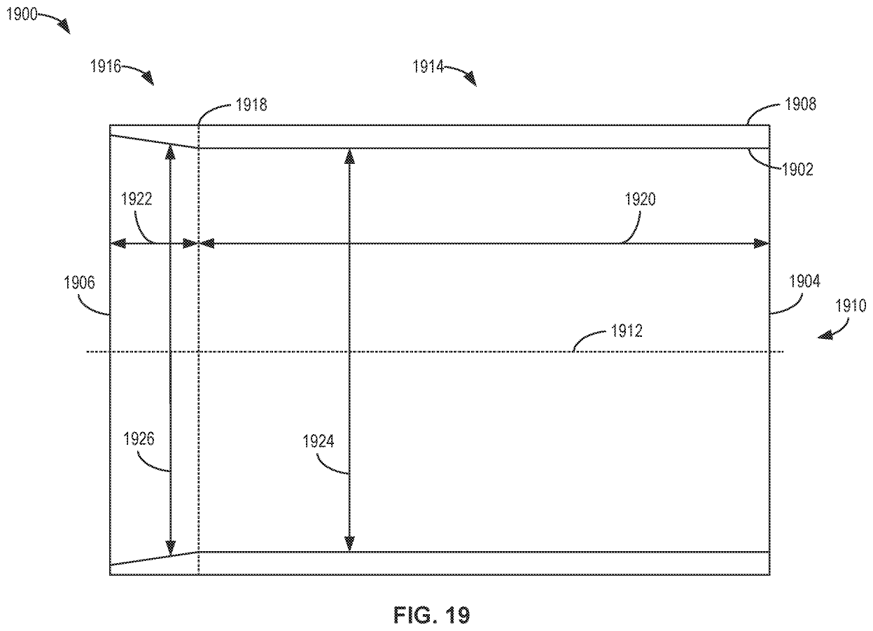

FIG. 19 illustrates a cross-sectional view of an example tapered crimp (e.g., a tapered crimp sleeve) 1900 constructed in accordance with teachings of this disclosure. In some examples, the tapered crimp 1900 of FIG. 19 can be used instead of the crimp 1724 of FIG. 18 to crimp (e.g., clamp) a tube onto a connector. In the illustrated example of FIG. 19, the tapered crimp 1900 includes an example inner surface 1902 extending between first and second example ends 1904, 1906 of the tapered crimp 1900, and an example outer surface 1908 extending between the first and second ends 1904, 1906. In this example, the inner surface 1902 defines an example longitudinal opening 1910 extending along an example longitudinal axis 1912 of the tapered crimp 1900. Further, the tapered crimp 1900 includes a first crimp section (e.g., a first crimp segment, a cylindrical crimp section) 1914 and a second crimp section (e.g., a second crimp segment, a tapered crimp section) 1916 adjacent the first crimp section 1914.

In this example, the first crimp section 1914 extends between the first end 1904 and an example point 1918 along the tapered crimp 1900 between the first and second ends 1904, 1906, and the second crimp section 1916 extends between the point 1918 and the second end 1906. In the illustrated example, the point 1918 is closer to the second end 1906 than the first end 1904. As such, a first example length (e.g., a first elongate length) 1920 of the first crimp section 1914 is greater than a second example length (e.g., a second elongate length) 1922 of the second crimp section 1916, where the first and second lengths 1920, 1922 are measured along the longitudinal axis 1912. In this example, the first length 1920 is approximately 12.7 millimeters (mm), and the second length 1922 is approximately 2 mm. In some examples, the first length 1920 and/or the second length 1922 may be different. For example, the first length 1920 and/or the second length 1922 may be longer (e.g., greater than 12.7 mm and/or greater than 2 mm, respectively). In some examples, the point 1918 can be closer to the first end 1904 than the second end 1906 (e.g., such that the second length 1922 is greater than the first length 1920). In some examples, the point 1918 is approximately at the midpoint between the first end 1904 and the second end 1906. In some examples, the second length 1922 is selected based on a predicted location of stress on a tube on which the tapered crimp 1900 is to be implemented. For example, numerical simulation can be used to estimate a location of stress on the tube based on a cross-sectional diameter and/or wall thickness of the tube. In such examples, the second length 1922 is selected such that the second crimp section 1916 contacts and/or overlaps the location of stress on the tube.

In the illustrated example, the first and second crimp sections 1914, 1916 have a circular cross-sectional shape. In some examples, a different cross-sectional shape (e.g., elliptical, rectangular, hexagonal, etc.) may be used for the first and second crimp sections 1914, 1916 instead. In some examples, a cross-sectional shape of the longitudinal opening 1910 corresponds to the cross-sectional shape of the first and second crimp sections 1914, 1916. In some examples the cross-sectional shape of the longitudinal opening 1910 can be different from the cross-sectional shape of the first and second crimp sections 1914, 1916 (e.g., the longitudinal opening 1910 can have a circular cross-sectional shape and the first and second crimp sections 1914, 1916 have a hexagonal cross-sectional shape, etc.).

In this example, the first and second crimp sections 1914, 1916 are metal (e.g., steel). In some examples, a different material can be used for the first crimp section 1914 and/or the second crimp section 1916. In this example, the first crimp section 1914 and the second crimp section 1916 are integrally formed (e.g., continuous). In some examples, the first crimp section 1914 and the second crimp section 1916 are manufactured separately, then coupled together (e.g., by welding or soldering the first crimp section 1914 to the second crimp section 1916, by providing an adhesive layer between the first and second crimp sections 1914, 1916, etc.). In some examples, the tapered crimp 1900 is manufactured by roll forming a metal sheet. In some examples, the tapered crimp 1900 is manufactured by extruding metal material. In some examples, the tapered crimp 1900 is manufactured by machining (e.g., boring) the longitudinal opening 1910 in a metal cylinder. In some examples, the tapered crimp 1900 is manufactured using additive manufacturing.

In the illustrated example, an inner diameter of the inner surface 1902 is different at different points along the longitudinal axis 1912 of the tapered crimp 1900. For example, the inner surface 1902 along the first crimp section 1914 has a first example inner diameter 1924, and the inner surface 1902 along the second crimp section 1916 has a second example inner diameter 1926. In this example, the first inner diameter 1924 is substantially constant (e.g., not increasing nor decreasing) along the first length 1920. Conversely, in this example, the second inner diameter 1926 is variable (e.g., not constant) along the second length 1922. In particular, the second inner diameter 1926 increases (e.g., gradually increases) from the point 1918 to the second end 1906 (e.g., decreases from the second end 1906 to the point). Stated differently, in this example, the inner surface 1902 of the tapered crimp 1900 along the second crimp section 1916 is angled relative to the longitudinal axis 1912 of the tapered crimp 1900. In this example, the second inner diameter 1926 at the point 1918 is substantially the same as the first inner diameter 1924. Further, the second inner diameter 1926 is greater than the first inner diameter 1924 at the second end 1906.

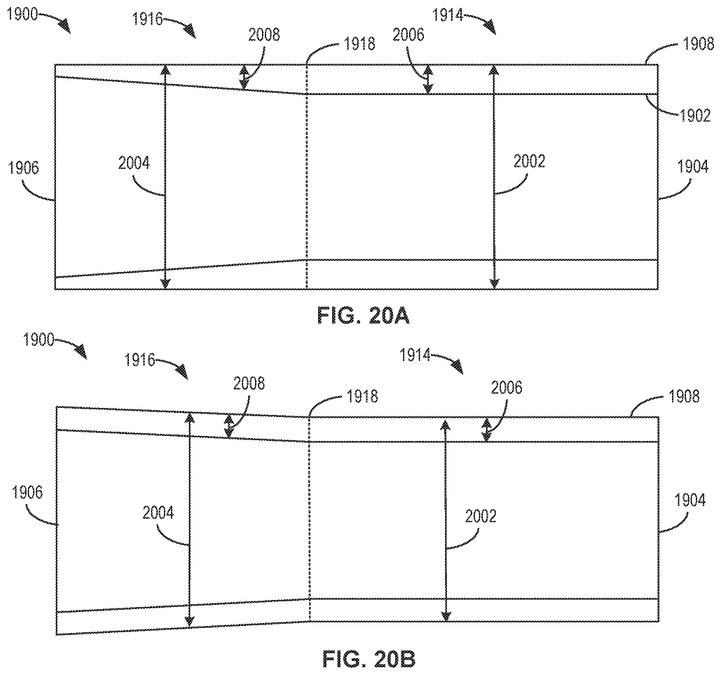

FIG. 20A illustrates a cross-sectional view of an alternative implementation of the example tapered crimp 1900 of FIG. 19. In particular, in the alternative implementation of the tapered crimp 1900 in FIG. 20A, the point 1918 is closer to a midpoint between the first and second ends 1904, 1906 compared to the point 1918 shown in FIG. 19. In the illustrated example of FIG. 20A, an outer diameter of the outer surface 1908 is constant (e.g., substantially constant. not changing, not increasing nor decreasing) between the first and second ends 1904, 1906 of the tapered crimp 1900. For example, the outer surface 1908 of the first crimp section 1914 has a first example outer diameter 2002 that is substantially constant between the first end 1904 and the point 1918, and the outer surface 1908 of the second crimp section 1916 has a second example outer diameter 2004 that is substantially constant between the point 1918 and the second end 1906, where the first outer diameter 2002 corresponds (e.g., is equal) to the second outer diameter 2004.

In the illustrated example, the first crimp section 1914 has a first example wall thickness 2006 that is substantially constant (e.g., not changing) between the first end 1904 and the point 1918, where the first wall thickness 2006 corresponds to a radial distance between the inner and outer surfaces 1902, 1908 of the tapered crimp 1900. In this example, the second crimp section 1916 has a second example wall thickness 2008 that is variable (e.g., not constant) between the point 1918 and the second end 1906. In particular, the second wall thickness 2008 decreases (e.g., gradually decreases, reduces) from the point 1918 to the second end 1906 (e.g., increases from the second end 1906 to the point 1918). In this example, the second wall thickness 2008 at the point 1918 is equal to the first wall thickness 2006. Further, in this example, the second wall thickness 2008 at the second end 1906 is less than (e.g., approximately half) the second wall thickness 2008 at the point 1918. In some examples, the second wall thickness 2008 at the point is at least twice the second wall thickness 2008 at the second end 1906.

FIG. 20B illustrates a cross-sectional view of the tapered crimp 1900 of FIG. 20A having a different shape of the outer surface 1908. For example, an outer diameter of the outer surface 1908 in FIG. 20B is different at different points along the tapered crimp 1900. In this example, while the first outer diameter 2002 of the first crimp section 1914 is substantially constant between the first end 1904 and the point 1918, the second outer diameter 2004 of the second crimp section 1916 is variable (e.g., not constant) between the point 1918 and the second end 1906. For example, the second outer diameter 2004 increases (e.g., gradually increases) from the point 1918 to the second end 1906 or, in the alternative, the second outer diameter 2004 decreases from the second end 1906 to the point 1918. In the illustrated example of FIG. 20B, the first wall thickness 2006 is substantially constant (e.g., not changing) between the first end 1904 and the point 1918, and the second wall thickness 2008 is substantially constant between the point 1918 and the second end 1906, where the second wall thickness 2008 corresponds to (e.g., is equal to) the first wall thickness 2006. In some examples, with the outer diameter 2004 of the second crimp section 1916 increasing towards the second end 1906 of the tapered crimp 1900, the inner diameter 1926 of the second crimp section 1916 at the second end 1906 of the tapered crimp 1900 can be equal to or greater than the outer diameter 2002 of the tapered crimp 1900 at the first end 1904. In some examples, the outer diameter 2004 of the second crimp section 1916 increases towards the second end 1906 of the tapered crimp 1900 at a different angle than the inner diameter 1926 of the second crimp section 1916 such that the second wall thickness 2008 differs along the length of the of the second crimp section 1916 as both inner and outer diameters increase.

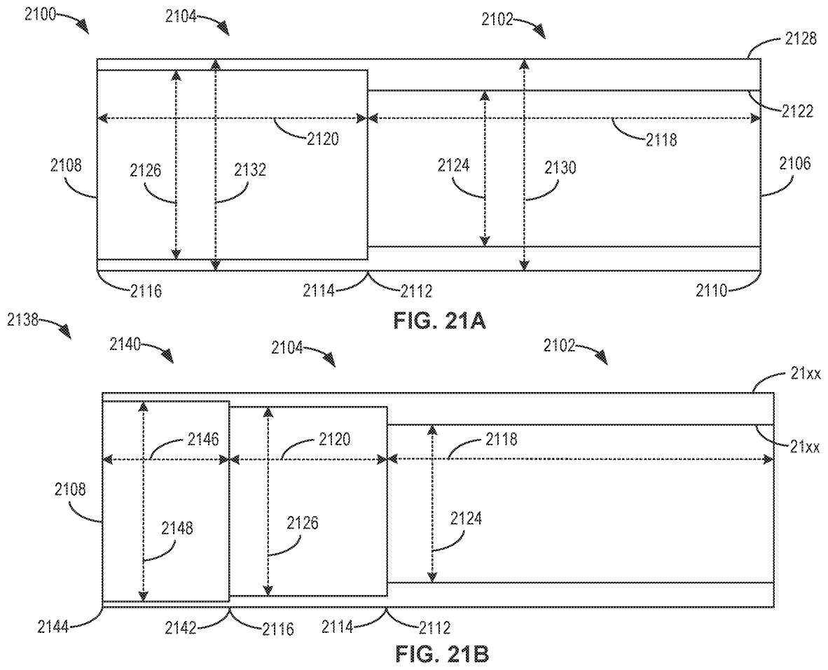

FIG. 21A illustrates a cross-sectional view of an example stepped crimp (e.g., a stepped crimp sleeve) 2100 constructed in accordance with teachings of this disclosure. In some examples, the stepped crimp 2100 can be used instead of the tapered crimp 1900 of FIGS. 19, 20A, and/or 20B and/or the crimp 1724 of FIG. 18 to crimp (e.g., clamp) a tube onto a connector. In the illustrated example of FIG. 21A, the example stepped crimp 2100 includes a first example crimp segment (e.g., a first crimp section) 2102 and a second example crimp segment (e.g., a second crimp section) 2104 extending between first and second example ends 2106, 2108 of the stepped crimp 2100. In particular, the first crimp segment 2102 extends between first and second example points 2110, 2112 along an elongate length of the stepped crimp 2100, and the second crimp segment 2102 extends between third and fourth example points 2114, 2116 along the elongate length of the stepped crimp 2100. In this example, the first point 2110 corresponds to the first end 2106, the fourth point 2116 corresponds to the second end 2108, and the second point 2112 corresponds to the third point 2114. In this example, a first example length 2118 of the first crimp segment 2102 is greater than a second example length 2120 of the second crimp segment 2104. In some examples, the second length 2120 can be the same or greater than the first length 2118.

In the illustrated example of FIG. 21A, an example inner surface 2122 of the stepped crimp 2100 has a first example inner diameter 2124 between the first and second points 2110, 2112, and a second example inner diameter 2126 between the third and fourth points 2114, 2116. In this example, the second inner diameter 2126 is greater than the first inner diameter 2124. Further, an example outer surface 2128 of the stepped crimp 2100 has a first example outer diameter 2130 between the first and second points 2110, 2112, and a second example outer diameter 2132 between the third and fourth points 2114, 2116. In this example, the second outer diameter 2132 is equal to the first outer diameter 2130 such that the stepped crimp 2100 has a substantially constant outer diameter along an entire length of the stepped crimp 2100 between the first and second ends 2106, 2108. In some examples, the second outer diameter 2132 is greater than the first outer diameter 2130. In the illustrated example, a first wall thickness (e.g., measured between the inner and outer surfaces 2122, 2128) of the first crimp segment 2102 is greater than a second wall thickness of the second crimp segment 2104. In some examples, the second wall thickness of the second crimp segment 2104 corresponds (e.g., is equal) to or is greater than the first wall thickness of the first crimp segment 2102.

In the illustrated example, the first and second crimp segments 2102, 2104 are metal (e.g., steel). In some examples, a different material can be used for the first crimp segment 2102 and/or the second crimp segment 2104. In this example, the first crimp segment 2102 and the second crimp segment 2104 are manufactured by at least one of roll-forming, extrusion, machining, boring, or additive manufacturing. In some examples, the first and second segments 2102 are manufactured together from a continuous material. In some examples, the first and second crimp segments 2102 are manufactured separately, then coupled together to produce the stepped crimp 2100.

In some examples, the first and second crimp segments 2102, 2104 are integrally formed in the stepped crimp 2100 such that crimping (e.g., tightening) of the stepped crimp 2100 causes the first and second crimp segments 2102, 2104 to be crimped (e.g., tightened) simultaneously. In such examples, the first and second inner diameters 2124, 2126 are reduced by a same amount during crimping. Alternatively, in some examples, the first and second crimp segments 2102, 2104 can be crimped independently. For example, the first crimp segment 2102 can be crimped (e.g., the first inner diameter 2124 can be reduced) by a first amount, and the second crimp segment 2104 can be crimped (e.g., the second inner diameter 2124 can be reduced) by a second amount different from the first amount. In some examples, the first and second crimp segments 2102, 2104 are manufactured to have different inner diameters (e.g., different first and second inner diameters 2124, 2126 of FIG. 21A) prior to crimping of the stepped crimp 2100.

FIG. 21B illustrates a cross-sectional view of a second example stepped crimp 2138. The second stepped crimp 2138 generally corresponds to the stepped crimp 2100 of FIG. 21A, and further includes a third example crimp segment 2140 proximate (e.g., adjacent) the second crimp segment 2104. In the illustrated example of FIG. 21B, the third crimp segment 2140 extends between fifth and sixth example points 2142, 2144 along the second stepped crimp 2138, where the fifth point 2142 corresponds to the fourth point 2116 and the sixth point 2144 corresponds to the second end 2108. In this example, a third example length 2146 of the third crimp segment 2140 is less than the second length 2120 of the second crimp segment 2104 and/or the first length 2118 of the first crimp segment 2102. In some examples, the third length 2146 is greater than or equal to the first length 2118 or the second length 2120. Further, the third crimp segment 2140 has a third example inner diameter 2148 greater than the first inner diameter 2124 of the first crimp segment 2102 and greater than the second inner diameter 2126 of the second crimp segment 2104. In the illustrated example, a third wall thickness of the third crimp segment 2140 is less than the first wall thickness of the first crimp segment 2102 and less than the second wall thickness of the second crimp segment 2104. In some examples, the first, second, and third crimp segments 2102, 2104, 2140 can have the same wall thickness. While the second stepped crimp 2138 of FIG. 21B includes three of the crimp segments 2102, 2104, 2140, a different number (e.g., four, five, etc.) of the crimp segments 2102, 2105, 2140 may be used instead. As noted above, in some examples, the outer diameter 2131 of the second crimp segment 2104 may be substantially constant and consistent with the outer diameter of the first crimp segment 2102. However, in other examples, the outer diameter 2131 of the second crimp segment 2104 changes at different points along its length. In some examples, the changes follow a stepped profile corresponding to the stepped profile of the inner surface of the second crimp segment 2014. In other examples, the outer diameter 2131 increases gradually (e.g., similar to the outer diameter 2004 shown in FIG. 20B).

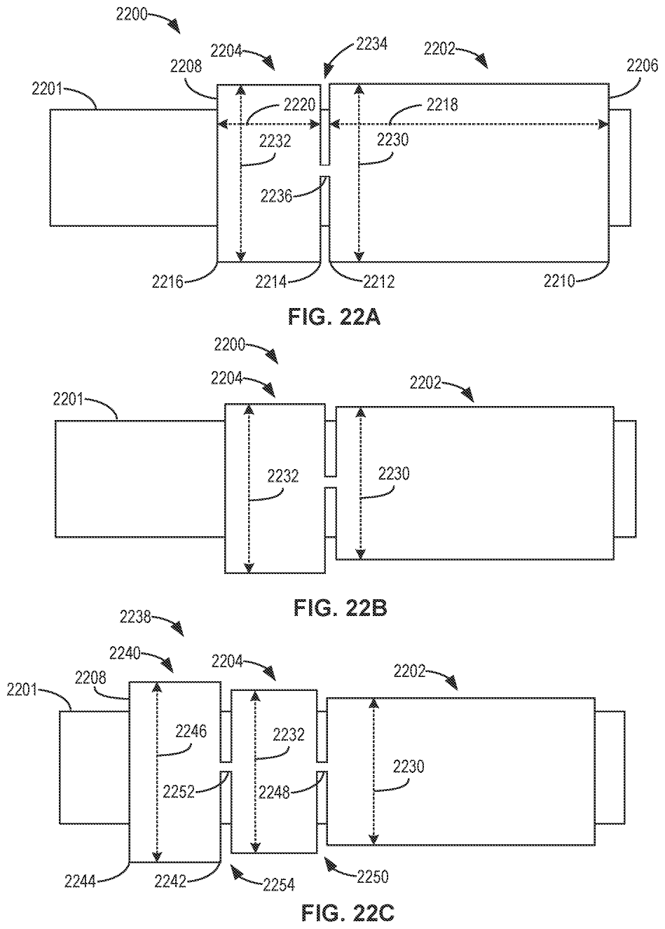

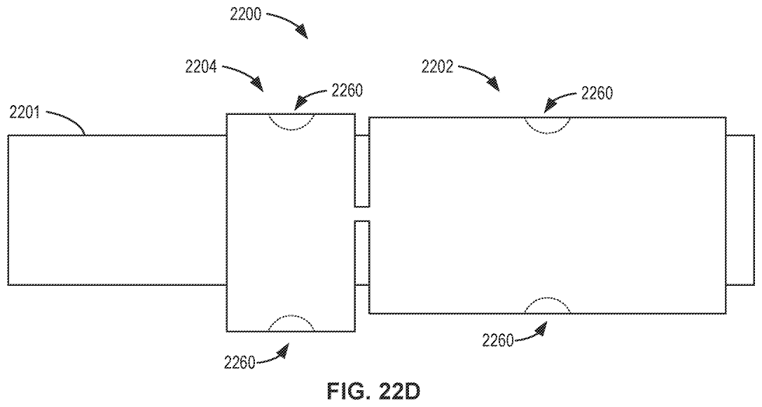

FIG. 22A illustrates an example piecewise crimp 2200 constructed in accordance with teachings of this disclosure. In the illustrated example of FIG. 22A, the piecewise crimp 2200 is implemented on an example tube 2201, and the piecewise crimp 2200 is uncrimped. In this example, the piecewise crimp includes a first crimp segment 2202 and a second example crimp segment 2204 extending between first and second example ends 2206, 2208 of the piecewise crimp 2200. In particular, the first crimp segment 2202 extends between first and second example points 2210, 2212 along an elongate length of the piecewise crimp 2200, and the second crimp segment 2202 extends between third and fourth example points 2214, 2216 along the elongate length of the piecewise crimp 2200. In this example, a first example length 2218 of the first crimp segment 2202 is greater than a second example length 2220 of the second crimp segment 2204. In some examples, the second length 2220 can be the same or greater than the first length 2218.

In the illustrated example of FIG. 22A, prior to crimping of the piecewise crimp 2200, a first example outer diameter 2230 of the first crimp segment 2202 corresponds (e.g., is equal) to the second outer diameter 2232 of the second crimp segment 2204. Additionally or alternatively, the first crimp segment 2202 and the second crimp segment 2204 can have the same inner diameter prior to crimping. In this example, the first point 2210 of the first crimp segment 2202 corresponds to the first end 2206 of the piecewise crimp 2200, and the fourth point 2216 of the second crimp segment 2204 corresponds to the second end 2208 of the piecewise crimp 2200. In this example, the second point 2212 of the first crimp segment 2202 is spaced apart from the third point 2214 of the second crimp segment 2204, such that an example gap 2234 is defined between the first and second crimp segments 2202, 2204. In some examples, the gap 2234 enables the first and second crimp segments 2202, 2204 to be crimped (e.g., tightened) independently. In this example, the gap 2234 is less than the first length 2218 of the first crimp segment 2202 and/or less than the second length 2220 of the second crimp segment 2204. In some examples, a size of the gap 2234 is selected based on one or more thresholds. For example, the size of the gap 2234 is greater than or equal to a first threshold based on manufacturing tolerances. Additionally or alternatively, the size of the gap 2234 is less than or equal to a second threshold greater than the first threshold, where the second threshold is determined based on numerical simulation of stresses on the tube 2201. In some such examples, the gap 2234 being greater than the second threshold is associated with a reduced effectiveness of the piecewise crimp 2200.

In the illustrated example, the piecewise crimp 2200 includes an example tab 2236 to bridge the gap 2234 and/or to couple the first crimp segment 2202 to the second crimp segment 2204. In some examples, the gap 2234 and the tab 2236 are produced by removing material between the first and second crimp segments 2202, 2204 during manufacture, such that the tab 2236 is integrally formed in the piecewise crimp 2200. In some examples, when the first and second crimp segments 2202, 2204 are manufactured separately, the tab 2236 is coupled between the first and second crimp segments 2202, 2204 after manufacture to define the gap 2234. While the one tab 2236 is shown in FIG. 22A, multiple tabs may be spaced around a circumference of the piecewise crimp 2200.

FIG. 22B illustrates the example piecewise crimp 2200 of FIG. 22A crimped on the example tube 2201. In the illustrated example of FIG. 22B, the first and second crimp segments 2202, 2204 are crimped (e.g., tightened) independently. In particular, the first crimp segment 2202 is crimped by a first amount, and the second crimp segment 2204 is crimped by a second amount less than the first amount. As a result of the crimping, the first outer diameter 2230 is less than the second outer diameter 2232 in FIG. 22B.

FIG. 22C illustrates a second example piecewise crimp 2238 crimped on the example tube 2201. In the illustrated example of FIG. 22C, the second piecewise crimp 2238 includes the first and second crimp segments 2202, 2204 of the piecewise crimp 2200 of FIGS. 22A and/or 22B, and further includes a third example crimp segment 2240 proximate (e.g., adjacent) the second crimp segment 2204. In the illustrated example of FIG. 22C, the third crimp segment 2240 extends between fifth and sixth example points 2242, 2244 along the second piecewise crimp 2238, where the sixth point 2244 corresponds to the second end 2208. In some examples, prior to crimping, the first, second, and third crimp segments 2202, 2204, 2240 of the second piecewise crimp 2238 have a same cross-sectional size (e.g., a same outer diameter and/or a same inner diameter). In the illustrated example of FIG. 22C, the first, second, and third crimp segments 2202, 2204, 2240 are crimped (e.g., tightened) independently to different cross-sectional sizes. In particular, the first crimp segment 2202 is crimped by a first amount, the second crimp segment 2204 is crimped by a second amount less than the first amount, and the third crimp segment 2240 is crimped by a third amount less than the first amount and less than the second amount. As a result, the first outer diameter 2230 of the first crimp segment 2202 is less than the second outer diameter 2232 of the second crimp segment 2204 and less than a third example diameter 2246 of the third crimp segment 2240.

In the illustrated example, a first example tab 2248 bridges a first example gap 2250 to couple the first crimp segment 2202 to the second crimp segment 2204, and a second example tab 2252 bridges a second example gap 2254 to couple the second crimp segment 2204 to the third crimp segment 2240. In some examples, one or more additional tabs may be coupled between the first crimp segment 2202 and the second crimp segment 2204 and/or between the second crimp segment 2204 and the third crimp segment 2240. In the illustrated example, the tabs 2248, 2252 are axially aligned along a length of the second piecewise crimp 2238. In other examples, the tabs 2248, 2252 may be axially offset relative to one another along the elongate length of the second piecewise crimp 2200.

FIG. 22D illustrates the example piecewise crimp 2200 of FIG. 22B including example indentations 2260 generated as a result of crimping on the example tube 2201. In the illustrated example of FIG. 22D, the piecewise crimp 2200 includes the indentations 2260 on opposite sides of the first and second crimp segments 2202, 2204. In some examples, the indentations 2260 are generated by a crimp tool as a result of crimping of the first and second crimp segments 2202, 2204. In some examples, a size and/or shape of the indentations 2260 is based on a corresponding shape of the crimp tool and/or a magnitude of force of the crimp tool onto the first and second crimp segments 2202, 2204. For example, the indentations 2260 are semicircular in this example. In other examples, the shape of the indentations 2260 can be different (e.g., triangular, rectangular, etc.). In some examples, a crimp tool can have a surface that is approximately the same length as the crimp segments 2202, 2204 to substantially uniformly compress or crimp substantially the entire length of each crimp segment 2202, 2204. As such, in some examples, an indentation may not be apparent as shown in the illustrated example.

In some examples, a different number of the indentations 2260 may be formed in the first and second crimp segments 2202, 2204. For example, the piecewise crimp 2200 can be crimped at multiple locations along an elongate length of the first and second crimp segments 2202, 2204, such that the crimp tool forms multiple ones of the indentations 2260 in the piecewise crimp 2200 along the elongate length. In some examples, the first crimp segment 2202 can be crimped prior to crimping of the second crimp segment 2204. Alternatively, in some examples, the second crimp segment 2204 can be crimped prior to crimping of the first crimp segment 2202. In some examples, the first and second crimp segments 2202, 2204 can be crimped simultaneously by the same crimp tool or by multiple crimp tools.

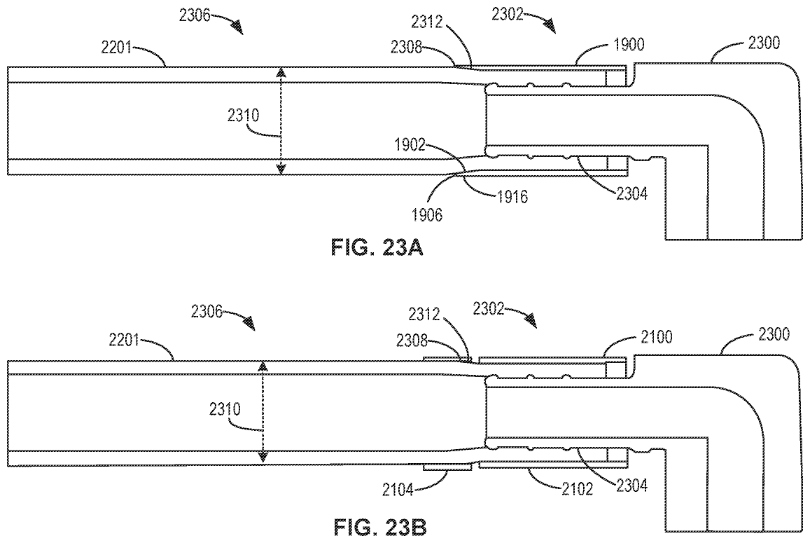

FIG. 23A illustrates the example tapered crimp 1900 of FIGS. 19 and/or 20A crimping (e.g., clamping) the example tube 2201 onto an example connector (e.g., a fitting, a barbed fitting) 2300. In the illustrated example of FIG. 23A, the tapered crimp 1900 is positioned on and/or surrounds an example end portion 2302 of the tube 2201, and the end portion 2302 surrounds (e.g., circumscribes) an example barbed portion 2304 of the connector 2300. In this example, the tapered crimp 1900 is tightened (e.g., clamped, crimped) to a reduced cross-sectional size (e.g., less than a cross-sectional size of an example uncrimped portion 2306 of the tube 2201). As a result, the tapered crimp 1900 sealably couples an outer surface of the barbed portion 2304 to an inner surface of the end portion 2302 to reduce and/or prevent leakage of fluid from the tube 2201 and/or the connector 2300.

In some examples, crimping of the end portion 2302 of the tube 2201 results in stress concentrated at an example location 2308 of the tube 2201 at which a cross-sectional size (e.g., an example outer diameter 2310) of the tube 2201 begins to decrease from the uncrimped portion 2306 to the crimped portion 2302. In the illustrated example, by crimping the second crimp section 1916 onto the tube 2201, the tapered inner surface 1902 of the second crimp section 1916 contacts an example outer surface 2312 of the tube 2201 to provide a gradual increase in the stress on the tube 2201 between the crimped and uncrimped portions 2302, 2306. As such, by distributing the stress across the outer surface 2312 of the tube 2201, the second crimp section 1916 reduces concentration of the stress at the location 2308 and, thus, reduces and/or prevents creep deformation and/or failure (e.g., rupture) of the tube 2201.

FIG. 23B illustrates the example piecewise crimp 2200 of FIGS. 22A and/or 22B crimping (e.g., clamping) the example tube 2201 onto the example connector 2300 of FIG. 23A. In the illustrated example of FIG. 23B, the first crimp segment 2202 of the piecewise crimp 2200 crimps the end portion 2302 of the tube 2201 onto the barbed portion 2304 of the connector 2300 to sealably couple the outer surface of the barbed portion 2304 to the inner surface of the end portion 2302. In this example, the second crimp segment 2204 is positioned and/or crimped onto the tube 2201 at the example location 2308 at which stress is likely to be concentrated due to crimping of the end portion 2302. In such examples, the second crimp segment 2204, like the second crimp section 1916 of FIG. 23A, reduces the stress concentrated at the location 2308 by distributing the stress across the outer surface 2312 of the tube 2201.

In some examples, the second example end 2208 is approximately as close to the barbed portion 2304 of the connector 2300 as the first example end 2206 is to the barbed portion 2304 inasmuch as both crimp segments 2202, 2204 of the crimp surround the barbed portion 2304. However, in some examples, the second crimp segment 2204 extends beyond an end of the barbed portion 2304. In some examples, the second crimp segment 2204 is entirely beyond an end of the barbed portion 2304 (e.g., does not overlap the barbed portion 2304). In some examples, a portion of the second crimp segment 2204 overlaps the barbed portion 2304. In some examples, the second crimp segment 2204 entirely overlaps the barbed portion 2304, such that the fourth point 2216 of the second crimp segment 2204 is at (e.g., proximate) the end of the barbed portion 2304.

Further, in some examples, the example stepped crimps 2100, 2138 discussed above in connection with FIGS. 21A and 21B and/or the example piecewise crimps 2200, 2238 discussed above in connection with FIGS. 22A-22C can be modified to include a tapered inner surface and/or a tapered outer surface similar to the inner surface 1902 and/or the outer surface 1908 of the tapered crimp 1900 of FIGS. 19, 20A, and/or 20B. Further still, in some examples, any one of the tapered crimp 1900 and/or the stepped crimps 2100, 2138 can include gaps and/or tab between respective crimp segments similar to the gap 2234 and/or the tab 2236 of the piecewise crimp 2200 shown in FIGS. 22A and/or 22B. Thus, the different example crimps 1900, 2100, 2138, 2200, 2238 disclosed herein are not mutually exclusive. Rather, any feature or aspect disclosed in connection with any one of the example crimps 1900, 2100, 2138, 2200, 2238 can be used in combination with and/or used instead of any features or aspects disclosed in connection with any other one of the example crimps 1900, 2100, 2138, 2200, 2238.

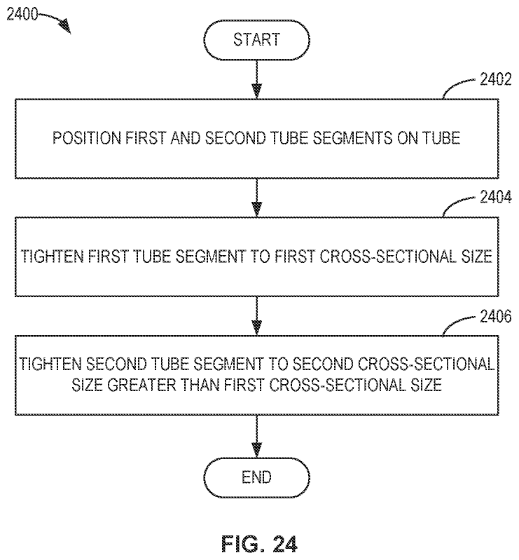

FIG. 24 is a flowchart representative of an example method 2400 of installing the example piecewise crimp 2200 of FIGS. 22A and/or 22B onto the example tube 2201 of FIG. 22A. Although the example method of installing is described with reference to the flowchart illustrated in FIG. 24, many other methods may alternatively be used. For example, the order of execution of the blocks may be changed, and/or some of the blocks described may be combined, divided, re-arranged, omitted, eliminated, and/or implemented in any other way.

The example method 2400 of FIG. 24 begins at block 2402 by positioning the first example crimp segment 2202 and the second example crimp segment 2204 on the example tube 2201 of FIGS. 23A and/or 23B. For example, the first and second crimp segments 2202, 2204 are positioned at the example end portion (e.g., a crimped portion) 2302 of the tube 2201 in which the example barbed portion 2304 of the example connector 2300 of FIGS. 23A and/or 23B is to be disposed. In some examples, the first and second crimp segments 2202, 2204 are positioned on the tube 2201 such that the first crimp segment 2202 is closer to the connector 2300 than the second crimp segment 2204 is to the connector 2300. For example, the first example end 2206 of the first crimp segment 2202 is to face the connector 2300, and the second example end 2208 of the second crimp segment 2204 is to face away from the connector 2300.

At block 2404, the example method 2400 includes tightening (e.g., crimping, clamping, reducing a cross-sectional size of) the first crimp segment 2202 to a first cross-sectional size. For example, the first crimp segment 2202 is tightened to a first inner diameter to clamp the end portion 2302 of the tube 2201 onto the barbed portion 2304 of the connector 2300. In some examples, the first inner diameter of the first crimp segment 2202 is less than an outer diameter of the uncrimped portion 2306 of the tube 2201. In some examples, the first crimp segment 2202 is tightened to sealably couple an inner surface of the end portion 2302 of the tube 2201 to an outer surface of the barbed portion 2304 of the connector 2300 to reduce and/or prevent leakage of fluid from the tube 2201 and/or the connector 2300.

At block 2406, the example method 2400 includes tightening the second crimp segment 2204 to a second cross-sectional size greater than the first cross-sectional size. For example, the second crimp segment 2204 is tightened to a second inner diameter less than the first inner diameter of the first crimp segment 2202. In some examples, the second crimp segment 2204 reduces stress concentrated at an outer surface of the tube 2201 and, thus, reduces and/or prevents failure (e.g., rupture) of the tube 2201. If the piecewise crimp 2200 includes additional discrete segments, the additional segments may be similarly tightened to different degrees to provide gradations in stress imposed on the tube 2201.

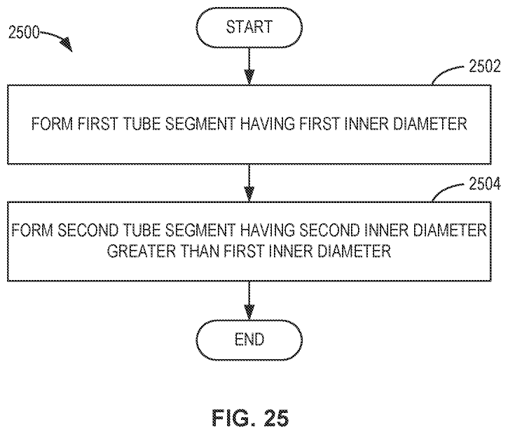

FIG. 25 is a flowchart representative of an example method 2500 of manufacturing the example tapered crimp 1900 of FIG. 19 and/or the example stepped crimp 2100 of FIG. 21A. In some examples, some or all of the operations outlined in the example method 2500 are performed automatically by fabrication equipment that is programmed to perform the operations. Although the example method of manufacturing is described with reference to the flowchart illustrated in FIG. 25, many other methods may alternatively be used. For example, the order of execution of the blocks may be changed, and/or some of the blocks described may be combined, divided, re-arranged, omitted, eliminated, and/or implemented in any other way.

The example method 2500 of FIG. 25 begins at block 2502 by forming (e.g., producing, fabricating) a first crimp segment (e.g., the first example crimp section 1914 of the tapered crimp 1900 and/or the first example crimp segment 2102 of the stepped crimp 2100) having a first inner diameter. For example, the first crimp section 1914 and/or the first crimp segment 2102 can be fabricated by roll-forming sheet metal to define a first inner surface and a first outer surface, where the first inner surface has the first inner diameter (e.g., the first inner diameter 1924 of FIG. 19 or the first inner diameter 2124 of FIG. 21A). In some examples, the first crimp section 1914 and/or the first crimp segment 2102 can be fabricated by extruding metal material having the first inner and outer surfaces. In some examples, the first crimp section 1914 and/or the first crimp segment 2102 can be fabricated by machining a metal material to define the first inner and outer surfaces. In some examples, the first crimp section 1914 and/or the first crimp segment 2102 can be fabricated by additive manufacturing (e.g., depositing layers of metal material to form the first inner and outer surfaces).

At block 2504, the example method 2500 includes forming a second crimp segment (e.g., the second example crimp section 1916 of the tapered crimp 1900 and/or the second example crimp segment 2104 of the stepped crimp 2100) having a second inner diameter greater than the first inner diameter. In some examples, the second crimp section 1916 and/or the second crimp segment 2104 can be fabricated via roll-forming, extrusion, machining, boring, and/or additive manufacturing to define a second inner surface and a second outer surface, where the second inner surface has the second inner diameter (e.g., the second inner diameter 1926 of FIG. 19 or the second inner diameter 2126 of FIG. 21A). In some examples, the second crimp segment can be manufactured with the first crimp segment (e.g., the first and second crimp segments are integrally formed). In some examples, the second crimp segment can be manufactured separately (e.g., independently) from the first crimp segment, and the second crimp segment can be coupled to the first crimp segment by welding, providing an adhesive layer between the first and second crimp segments, coupling the example tab 2236 of FIG. 22A between the first and second crimp segments, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

From the foregoing, it will be appreciated that example systems, methods, apparatus, and articles of manufacture have been disclosed that crimp a tube onto a connector of a liquid cooling system. Disclosed systems, methods, apparatus, and articles of manufacture provide a crimp sleeve including a first crimp segment adjacent a second crimp segment, where the first crimp segment is to have a first inner diameter and the second crimp segment is to have a second inner diameter greater than the first inner diameter after crimping. Examples disclosed herein sealably couple the tube to the connector by crimping of the first crimp segment. Furthermore, by crimping the second crimp segment at a location of the tube proximate the first crimp segment, examples disclosed herein reduce stress concentration on the tube resulting from crimping of the first crimp segment and, as a result, prevent and/or reduce likelihood of damage (e.g., creep and/or rupture) to the tube. Accordingly, disclosed systems, methods, apparatus, and articles of manufacture improve the efficiency of using a computing device by improving reliability of tubes in a liquid cooling system of the computing device, thus improving efficiency of cooling of the computing device by the liquid cooling system and, as a result, preventing overheating of the computing device. Disclosed systems, methods, apparatus, and articles of manufacture are accordingly directed to one or more improvement(s) in the operation of a machine such as a computer or other electronic and/or mechanical device.

Example methods, apparatus, systems, and articles of manufacture to crimp a tube are disclosed herein. Further examples and combinations thereof include the following:

Example 1 includes a crimp comprising a first crimp section extending between a first end of the crimp and a point along the crimp between the first end and a second end, a first inner diameter of the first crimp section constant between the first end and the point, and a second crimp section adjacent the first crimp section, the second crimp section extending between the point and the second end, a second inner diameter of the second crimp section to increase from the point to the second end.

Example 2 includes the crimp of example 1, wherein a first length of the first crimp section is greater than a second length of the second crimp section.

Example 3 includes the crimp of example 1, wherein a wall thickness of the second crimp section decreases from the point to the second end.

Example 4 includes the crimp of example 3, wherein the wall thickness at the point is at least twice the wall thickness at the second end.

Example 5 includes the crimp of example 1, wherein a first outer diameter of the first crimp section is constant between the first end and the point, and a second outer diameter of the second crimp section is constant between the point and the second end.

Example 6 includes the crimp of example 1, wherein a first outer diameter of the first crimp section is constant between the first end and the point, and a second outer diameter of the second crimp section is to increase from the point to the second end.

Example 7 includes the crimp of example 6, wherein a first wall thickness of the first crimp section corresponds to a second wall thickness of the second crimp section.

Example 8 includes the crimp of example 1, wherein the first and second crimp sections are metal.

Example 9 includes a crimp comprising a first crimp segment extending between first and second points along an elongate length of the crimp, the first crimp segment to have a first inner diameter at the first point, and a second crimp segment extending between third and fourth points along the elongate length of the crimp, the second and third points between the first and fourth points, the second crimp segment to have a second inner diameter at the fourth point, the second inner diameter greater than the first inner diameter.

Example 10 includes the crimp of example 9, wherein the second point is spaced apart from the third point to define a gap between the first crimp segment and the second crimp segment, the gap being less than a first length of the first crimp segment and less than a second length of the second crimp segment.

Example 11 includes the crimp of example 10, further including at least one tab to bridge the gap to couple the first crimp segment to the second crimp segment.

Example 12 includes the crimp of example 9, wherein the second point corresponds to the third point.

Example 13 includes the crimp of example 9, wherein a first length of the first crimp segment is greater than a second length of the second crimp segment.

Example 14 includes the crimp of example 9, further including a third crimp segment extending between fifth and sixth points along the elongate length of the crimp, the fourth and fifth points between the third and sixth points, the third crimp segment to have a third inner diameter at the sixth point, the third inner diameter greater than the first inner diameter and greater than the second inner diameter.

Example 15 includes the crimp of example 9, wherein the second crimp segment is to have a third inner diameter at the third point, the third inner diameter corresponding to the first inner diameter, the third inner diameter to gradually increase from the third point to the fourth point.

Example 16 includes the crimp of example 9, wherein the first crimp segment is to have a first outer diameter between the first and second points, the second crimp segment to have a second outer diameter gradually increasing from the third point to the fourth point.

Example 17 includes the crimp of example 9, wherein the second crimp segment is to have a first wall thickness at the third point and a second wall thickness at the fourth point, the first wall thickness at least twice the second wall thickness.

Example 18 includes a crimp comprising an outer surface extending between first and second ends of the crimp, and an inner surface extending between the first and second ends of the crimp, an inner diameter of the inner surface to be different at different points along an elongate length of the crimp.

Example 19 includes the crimp of example 18, wherein the inner diameter is to gradually decrease from the second end to a point between the first and second ends.

Example 20 includes the crimp of example 19, wherein an outer diameter of the outer surface is to gradually increase from the point to the second end.

Example 21 includes the crimp of example 18, wherein an outer diameter of the outer surface is to be constant along the elongate length of the crimp.

Example 22 includes the crimp of example 18, wherein a first wall thickness between the inner and outer surfaces at the first end is at least twice a second wall thickness between the inner and outer surfaces at the second end.

Example 23 includes a method to manufacture a crimp, the method comprising forming a first crimp segment between first and second points along an elongate length of the crimp, the first crimp segment to have a first inner diameter between the first and second points, and forming a second crimp segment between third and fourth points along the elongate length of the crimp, the second crimp segment to have a second inner diameter at the fourth point, the second inner diameter greater than the first inner diameter.

Example 24 includes the method of example 23, further including forming a gap between the second and third points.

Example 25 includes the method of example 24, further including coupling the first crimp segment to the second crimp segment via a tab to bridge the gap.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

What is claimed is:

1. A crimp comprising:
a first crimp section extending between a first end of the crimp and a point along the crimp between the first end and a second end, a first inner diameter of the first crimp section constant between the first end and the point; and
a second crimp section adjacent the first crimp section, the second crimp section extending between the point and the second end, a second inner diameter of the second crimp section to increase from the point to the second end.

2. The crimp of claim 1, wherein a first length of the first crimp section is greater than a second length of the second crimp section.

3. The crimp of claim 1, wherein a wall thickness of the second crimp section decreases from the point to the second end.

4. The crimp of claim 3, wherein the wall thickness at the point is at least twice the wall thickness at the second end.

5. The crimp of claim 1, wherein a first outer diameter of the first crimp section is constant between the first end and the point, and a second outer diameter of the second crimp section is constant between the point and the second end.

6. The crimp of claim 1, wherein a first outer diameter of the first crimp section is constant between the first end and the point, and a second outer diameter of the second crimp section is to increase from the point to the second end.

7. The crimp of claim 6, wherein a first wall thickness of the first crimp section corresponds to a second wall thickness of the second crimp section.

8. The crimp of claim 1, wherein the first and second crimp sections are metal.

9. A crimp comprising:
a first crimp segment extending between first and second points along an elongate length of the crimp, the first crimp segment to have a first inner diameter at the first point; and
a second crimp segment extending between third and fourth points along the elongate length of the crimp, the second and third points between the first and fourth points, the second crimp segment to have a second inner diameter at the fourth point, the second inner diameter greater than the first inner diameter.

10. The crimp of claim 9, wherein the second point is spaced apart from the third point to define a gap between the first crimp segment and the second crimp segment, the gap being less than a first length of the first crimp segment and less than a second length of the second crimp segment.

11. The crimp of claim 10, further including at least one tab to bridge the gap to couple the first crimp segment to the second crimp segment.

12. The crimp of claim 9, wherein the second point corresponds to the third point.

13. The crimp of claim 9, wherein a first length of the first crimp segment is greater than a second length of the second crimp segment.

14. The crimp of claim 9, further including a third crimp segment extending between fifth and sixth points along the elongate length of the crimp, the fourth and fifth points between the third and sixth points, the third crimp segment to have a third inner diameter at the sixth point, the third inner diameter greater than the first inner diameter and greater than the second inner diameter.

15. The crimp of claim 9, wherein the second crimp segment is to have a third inner diameter at the third point, the third inner diameter corresponding to the first inner diameter, the third inner diameter to gradually increase from the third point to the fourth point.

16. The crimp of claim 9, wherein the first crimp segment is to have a first outer diameter between the first and second points, the second crimp segment to have a second outer diameter gradually increasing from the third point to the fourth point.

17. The crimp of claim 9, wherein the second crimp segment is to have a first wall thickness at the third point and a second wall thickness at the fourth point, the first wall thickness at least twice the second wall thickness.

18. A crimp comprising:
an outer surface extending between first and second ends of the crimp; and
an inner surface extending between the first and second ends of the crimp, an inner diameter of the inner surface to be different at different points along an elongate length of the crimp.

19. The crimp of claim 18, wherein the inner diameter is to gradually decrease from the second end to a point between the first and second ends.

20. The crimp of claim 19, wherein an outer diameter of the outer surface is to gradually increase from the point to the second end.

21. The crimp of claim 18, wherein an outer diameter of the outer surface is to be constant along the elongate length of the crimp.

22. The crimp of claim 18, wherein a first wall thickness between the inner and outer surfaces at the first end is at least twice a second wall thickness between the inner and outer surfaces at the second end.

23. A method to manufacture a crimp, the method comprising:
forming a first crimp segment between first and second points along an elongate length of the crimp, the first crimp segment to have a first inner diameter between the first and second points; and
forming a second crimp segment between third and fourth points along the elongate length of the crimp, the second crimp segment to have a second inner diameter at the fourth point, the second inner diameter greater than the first inner diameter.

24. The method of claim 23, further including forming a gap between the second and third points.

25. The method of claim 24, further including coupling the first crimp segment to the second crimp segment via a tab to bridge the gap.
